(19) United States
(12) Patent Application Publication
(10) Pub. No.: US 2024/0384893 A1
(43) Pub. Date: Nov. 21, 2024

(54) RECIRCULATING ULTRA-PURE DEIONIZED WATER HEATER

(71) Applicant: Trebor International, Inc., West Jordan, UT (US)

(72) Inventors: Cory Dennis Shorr, Pine Canyon, UT (US); Craig Lee Jensen, West Jordan, UT (US); Allison Schmitz, West Jordan, UT (US); DJ Roy, West Jordan, UT (US); Anthony Pipitone, West Jordan, UT (US)

(73) Assignee: Trebor International, Inc., West Jordan, UT (US)

(21) Appl. No.: 18/668,403

(22) Filed: May 20, 2024

Related U.S. Application Data
(63) Continuation of application No. 18/667,618, filed on May 17, 2024.
(60) Provisional application No. 63/604,051, filed on Nov. 29, 2023.
(60) Provisional application No. 63/503,376, filed on May 19, 2023.

(51) Int. Cl. F24H 15/175; F24H 1/18; F24H 15/219; F24H 15/238; F24H 15/242; F24H 15/315; H01L 21/67

(52) U.S. Cl. CPC F24H 15/175; F24H 1/186; F24H 15/219; F24H 15/238; F24H 15/242; F24H 15/315; H01L 21/67017

(57) ABSTRACT

Provided herein are heating systems for ultra-pure deionized water. One heating system is a closed loop, dual input recirculating system that includes a tank and a trim heater. The tank accepts a flow of water from a cold water source and a flow of water from a heated water source. The system combines the cold and heated water to achieve a first temperature within the tank. The water is then heated from the first temperature to a second final temperature with the trim heater. The water, at the second, final temperature, is sent through a closed loop recirculating system for the use in a manufacturing process such as semiconductor manufacturing.

### CROSS REFERENCE TO RELATED APPLICATIONS

This application is a continuation of, and claims priority to U.S. application Ser. No. 18/667,618 filed on May 17, 2024. U.S. application Ser. No. 18/667,618 is a non-provisional application claiming priority to and the benefit of U.S. Provisional Application Ser. No. 63/503,376 filed on May 19, 2023 and U.S. Provisional Application Ser. No. 63/604,051 filed on Nov. 29, 2023. The aforementioned applications are incorporated herein by reference in their entities.

### FIELD OF THE INVENTION

The present disclosure is generally concerned with fluid systems and fluid system components. More specifically, at least some of the disclosed embodiments concern a water heater suitable for use with deionized water or ultra-pure water.

### BACKGROUND

Processes such as semiconductor manufacturing often require a flow of ultra-pure deionized water having a specific pressure and temperature, often within narrow ranges, notwithstanding changing flow conditions in the system. In recognition of this, various systems have been devised in an attempt to provide pressure and temperature stability in a flow of ultra-pure deionized water. For various reasons however, such approaches have not proven to be particularly effective or desirable. Therefore, there is a need for an improved system that addresses the inadequacies of current solutions.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

One or more techniques and systems described herein may be used to heat, recirculate, and provide deionized (DI) water or ultra-pure water (UPW) to a process system. These techniques and systems may offer significant improvements over current systems, such as improvements to efficiency, energy use, control accuracy, heating times, water usage, and the like. These improvements will be made evident by the disclosure herein.

In general, methods and systems of heating, circulating, and providing ultra-pure deionized water will be described herein. The systems and methods may solve one or more problems in the semiconductor manufacturing industry as many semiconductor processes require a supply of heated ultra-pure deionized water. The ultra-pure deionized water is often required to be stable in terms of at least its temperature, pressure, and flow rate. Further, such stability must be maintained notwithstanding that the water may be used for a variety of different processes, and may pass through various fluid systems and components. A stable supply of ultra-pure deionized water may enable a semiconductor process to maintain a desired yield in terms of product output, while also reducing the waste of energy, natural resources, and capital. The water heater and system described herein may have a small footprint so as to minimize the amount of occupied floor space. The heater may also be encompassed in a single enclosure which may make installation and integration with existing processes easy and timely compared to systems on the market.

In an implementation, a heating system comprises a first tank, a first stage heater in fluid communication with and located downstream of the first tank, the first stage heater configured to heat a fluid from the first tank to a first temperature, a second tank in fluid communication with and located downstream of the first stage heater, the second tank configured to hold at least a portion of the fluid from the first stage heater, a second stage heater in fluid communication with and located downstream of the second tank, the second stage heater configured to heat at least a portion of the fluid from the second tank to a second temperature higher than the first temperature, an outlet valve in fluid connection with an outlet of the second stage heater and a first end of a fluid process loop, and a return valve in fluid connection with a second end of the process fluid loop and an input of the first tank, and wherein the fluid at the second temperature is configured to exit the heating system at the outlet valve such that the fluid circulates through the fluid process loop and returns back to the first tank through the return valve.

In another implementation, a method of heating a fluid with a two stage recirculating heating system, the heating system comprises a first stage heater, a second stage heater in fluid communication with and located downstream of the first stage heater, an outlet valve in fluid connection with an outlet of the second stage heater and a first end of a fluid process loop, and a return valve in fluid connection with a second end of the process fluid loop and an input of the first stage heater, wherein the method comprises heating a fluid to a first temperature with the first stage heater, routing the fluid from the first stage heater to the second stage heater, heating the fluid to a second temperature with the second stage heater, the second temperature greater than the first temperature, routing the heated fluid from an outlet of the second stage heater to a fluid process loop, the fluid is returned to the first stage heater via the return valve.

In another implementation, a heating system comprises a first stage heater configured to heat a fluid to a first temperature, a second stage heater in fluid communication with and located downstream of the first stage heater, the second stage heater configured to heat at least a portion of the fluid from the first temperature to a second temperature higher than the first temperature, an outlet valve in fluid connection with an outlet of the second stage heater and a first end of a fluid process loop, a return valve in fluid connection with a second end of the process fluid loop and an input of the first stage heater, and a pump located between the first stage heater and the second stage heater, the pump configured to pump the fluid through the process fluid loop, wherein the fluid is configured to exit the heating system at the outlet valve such that the fluid circulates through the fluid process loop and returns back to the first stage heater via the return valve, the fluid process loop is a closed loop system.

In another implementation, a heating system comprises a tank with a first input and a second input, the first input configured to accept a flow of water from a first water source and the second input configured to accept a flow of water from a second water source, the tank holding a volume of water at a first temperature, a heater in fluid communication with and located downstream of the tank, the heater configured to heat at least a portion of the fluid from the tank from the first temperature to a second temperature higher than the first temperature, an outlet valve in fluid connection with an outlet of the heater and a first end of a fluid process loop, and a return valve in fluid connection with a second end of the process fluid loop and a third input of the tank, and wherein the fluid at the second temperature is configured to exit the heating system at the outlet valve such that the fluid circulates through the fluid process loop and returns back to the tank through the third input of the tank, the tank configured to accept a flow of water from the first input, the second input, and the third input and to combine each flow of water to achieve a desired temperature of the volume of water in the tank.

In another implementation, a system comprises an ambient temperature water source, a heated water source, a process system comprising at least one process tool, a heater system, comprising a tank with a first input and a second input, the first input configured to accept a flow of water from the ambient temperature water source and the second input configured to accept a flow of water from the heated water source, the tank holding a volume of water at a first temperature, a heater in fluid communication with and located downstream of the tank, the heater configured to heat at least a portion of the fluid from the tank from the first temperature to a second temperature higher than the first temperature, an outlet valve in fluid connection with an outlet of the heater and a first end of a fluid process loop, a return valve in fluid connection with a second end of the process fluid loop and a third input of the tank, and wherein the fluid at the second temperature is configured to exit the heating system at the outlet valve such that the fluid circulates through the fluid process loop and returns back to the tank through the third input of the tank, the tank configured to accept a flow of water from the first input, the second input, and the third input and to combine each flow of water to achieve a desired temperature for the volume of water in the tank.

To the accomplishment of the foregoing and related ends, the following description and annexed drawings set forth certain illustrative aspects and implementations. These are indicative of but a few of the various ways in which one or more aspects may be employed. Other aspects, advantages and novel features of the disclosure will become apparent from the following detailed description when considered in conjunction with the annexed drawings.

### BRIEF DESCRIPTION OF THE DRAWINGS

What is disclosed herein may take physical form in certain parts and arrangement of parts, and will be described in detail in this specification and illustrated in the accompanying drawings which form a part hereof and wherein:

FIG. 1 is an exemplary component diagram of a system as described herein.

FIG. 2 is an exemplary component diagram of a recirculating heating system as described herein.

FIG. 3 is another exemplary component diagram of a recirculating heating system as described herein.

FIG. 4 is an exemplary piping and instrumentation diagram of a recirculating heating system as described herein.

FIG. 5 is an exemplary component diagram of a dual input recirculating heating system as described herein.

FIG. 6 is an exemplary component diagram of a modular configuration for any of the heating systems described herein.

FIG. 7 is an exemplary diagram of a point of use heating system installed in a sub-fabrication environment as described herein.

FIG. 8 is an exemplary diagram of a point of use heating system installed in a fabrication environment as described herein.

FIG. 9 is an exemplary diagram of a single pass heating system as described herein.

FIG. 10 is an exemplary diagram of a closed loop recirculating heating system as described herein.

FIG. 11 is an exemplary implementation of a heating element that may be used with any of the heating systems disclosed herein.

FIG. 12 is an exemplary implementation of a heating element that may be used with any of the heating systems disclosed herein.

FIG. 13 is an exemplary implementation of a first stage heater and a second stage heater illustrating various modules and tubes within the heating modules.

FIG. 14 is an exemplary graph of example performance characteristics of a single pass heater system having a constant flow rate.

FIG. 15 is an exemplary graph of example performance characteristics of a single pass heater system having a varied flow rate.

FIG. 16 is an exemplary graph of example performance characteristics of a closed loop recirculating heating system having a varied flow rate.

FIG. 17 is an exemplary implementation of a heater according to any of the systems described herein.

FIG. 18 is another exemplary implementation of a heater without side panels according to any of the systems described herein.

FIG. 19 is another exemplary implementation of the heater without side panels according to any of the systems described herein.

FIG. 20 is another exemplary implementation of the heater without side panels according to any of the systems described herein.

FIG. 21 is another exemplary implementation of the heater without side panels according to any of the systems described herein.

### DETAILED DESCRIPTION

The claimed subject matter is now described with reference to the drawings, wherein like reference numerals are generally used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, structures and devices are shown in block diagram form in order to facilitate describing the claimed subject matter.

Ultra-pure water (UPW) or deionized (DI) water may be used in a variety of different fluid systems and applications such as semiconductor manufacturing or pharmaceutical manufacturing, for example. In the semiconductor manufacturing industry, UPW may be used for the preparation, treatment, or cleaning of semiconductor components. Impurities in the water may damage semiconductor components or reduce overall efficiency. Therefore, maintaining the purity of the water can be critical to the semiconductor manufacturing process. In addition to the strict purity standards that are often required, the water is often maintained at a specific pressures, temperatures, and/or flow rates, often within small thresholds or tolerances. It can be difficult to heat ultra-pure water to within defined temperature thresholds quickly and can be even more difficult to maintain the desired pressure, temperature, or flow throughout a manufacturing process. Further yet, current systems can be inefficient and wasteful.

For example, in one conventional approach, a single pass, open-loop, heating system is employed in which ultra-pure deionized water, after being used in connection with the manufacturing process, is sent to a drain. Such an approach is wasteful, and not cost-effective due to at least the expense of replacing the water and having to reheat new water. In other approaches, large and complex recirculating systems that rely on open flow loops may be employed. Single pass systems (e.g., as opposed to recirculating systems) may refer to systems in which heated water is pumped to a process system and then sent to a drain after use rather than being sent back to the heater. Open loop systems (e.g., as opposed to closed loop systems) may refer to heating systems in which the pumped UPW or DI water is exposed to atmosphere as part of the process. When exposed to atmosphere, the quality of UPW or DI water may be affected, making recirculation back to the heater difficult or unfeasible.

As described herein, a closed loop, recirculating heating system may be provided that provides numerous advantages over conventional heating systems. The one or more techniques and systems described herein may be used to heat, recirculate, and provide deionized (DI) water and/or ultra-pure water (UPW) to a process system in a manner that offers significant improvements compared to current approaches. Such improvements may be with respect to efficiency, control accuracy, heating times, and the like.

By way of example, a re-circulating water heater, which may be compact in size, may comprise a control system, one or more heating elements of a single stage or a multi stage heating system, and a closed loop water recirculating system. The recirculating system may hold a volume of ultra-pure deionized water and the control system may function to maintain the pressure, flow, and temperature of the ultra-pure deionized water as it circulates through various components, such as elements of a semiconductor manufacturing system. The closed loop water recirculating system may be referred to herein as a process control loop, fluid process loop, closed loop system, recirculating loop, and the like. In an embodiment, the heating elements comprise thin film elements with a low thermal mass that may enable the heating elements to quickly heat, and cool according to requirements of a manufacturing process. The water heater, often referred to as a heating system, may also include one or more tanks or pressure vessels that may serve to hold water and/or even out or dampen temperature fluctuations of the deionized water before it leaves the water heater. In certain embodiments, the heater may have an input of cold water (or ambient temperature water), hot water (or heated water), or both.

The control system, which may comprise a controller or a PLC (programmable logic controller), may control the heating elements and their multiple stages. For instance, in a first stage performed by a first stage heater, bulk heating of cold ultra-pure deionized water may be performed by the first stage heater. Particularly, as the ultra-pure deionized water flows into contact with the heating elements, the heating elements heat the cold ultra-pure deionized water to a pre-heat temperature that is near a final setpoint temperature. In a second stage performed by a second heater, the second stage heater heats the ultra-pure deionized water from the pre-heat temperature to the final setpoint temperature. The deionized water at the final setpoint temperature may then be provided, for example, to one or more process tools of a semiconductor manufacturing system via the fluid process loop. After the deionized water leaves the fluid process loop, it returns to the water heater and the cycle is repeated. In certain implementations, ultra-pure deionized water that is used by a process tool or otherwise exposed to atmosphere or impurities may be sent to a drain rather than returning to the water heater. In this example, the water that remains in the closed loop system may return to the heater, and the water that is used by a process tool is sent to the drain. In this manner, the purity of the water in the closed loop is maintained for future use.

In another implementation, a dual input heater may be provided. The dual input heater may be similar to the re-circulating heater, but may accept inputs of both cold (ambient temperature) water as well as heated water. The water may be UPW or DI water. In this implementation, the heater may combine cold UPW and hot UPW to achieve a desired temperature. Once combined, the UPW may be sent to a holding tank and then to a trim heater, where the combined UPW is increased to a final temperature for use in a process system. The trim heating may be accomplished using single or multiple stage heating. It should be appreciated that a dual input heater such as this may be beneficial for numerous reasons. For instance, by splitting the control and heating into separate stages more precise control and flexibility may be achieved. It may also reduce energy consumption and optimize efficiency while utilizing a smaller footprint compared to conventional systems.

When referenced herein, ultra-pure water (UPW) may take on the ordinary meaning as understood in the industry. For instance, UPW may be water with very little or no: particles, bacterial, organic carbons, silica, or other impurities. Deionized (DI) water may also take on the ordinary meaning as understood in the industry. For instance, DI water may be water that has been removed of ions. Ions are electrically charged atoms or molecules found in water that have either a net negative or positive charge. It should be appreciated that the systems and methods described herein may be used in conjunction with either, or both, of ultra-pure water or deionized water. In other embodiments, the systems and methods described herein may be used with any fluid without deviating from the scope of the disclosure. Note that as used herein, “fluid” is also intended to be broadly construed and embraces gases, liquids, combinations of gases and liquids, and combinations of one or more gases and/or one or more liquids with solids.

The systems and methods disclosed herein may be used in a variety of different applications, and may be particularly useful in fluid systems for semiconductor manufacturing processes, although the scope of the invention is not limited to such applications. Such fluid systems may employ, for example, ultra-pure and/or deionized water, corrosive agents and materials including but not limited to acids and bases, gases, other fluids, and combinations of any of the foregoing. Such fluids may be hot, highly pressurized, reactive, and/or pure fluids. For example, some process systems, such as semiconductor manufacturing systems, may employ process fluids that may be maintained at a temperature of about 120 degrees C., or higher. As another example, some systems may employ process fluids that may reach temperatures as high as about 200 degrees C. to about 220 degrees C., or higher. Yet other systems may employ process fluids that may reach temperatures between 50 degrees C. to about 100 degrees C.

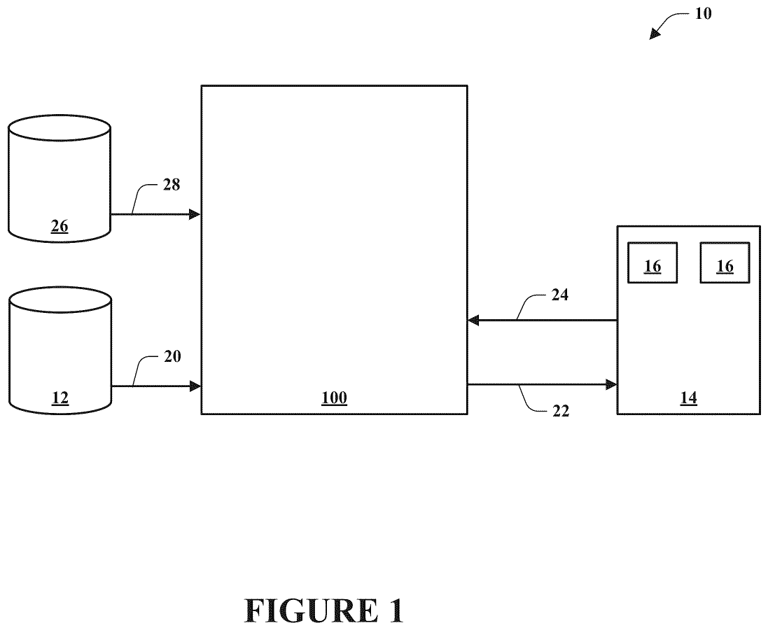

FIG. 1 illustrates an exemplary system 10, such as an industrial system 10 that may utilize any of the systems or methods disclosed herein. System 10 may comprise an ambient (or cold) water source 12, a hot water source 26, a process system 14, and a heating system 100. The ambient water source 12 may supply or store any ambient or cold temperature fluid or water, such as ultra-pure deionized water to be used by the process system 14. The hot water source 26 may supply or store any hot temperature fluid or water, such as ultra-pure deionized water to be used by the process system 14. In some examples, the ambient temperature water source 12 is a fluid tank, lake, reservoir, or piping of ambient temperature water. In some examples, the hot water source 26 is a fluid tank, boiler, natural gas heating system, or piping of ambient temperature water. It should be appreciated that the ambient temperature source 12 or the hot water source 26 may be any suitable source of fluid, such as UWP or DI water. They may be standalone sources, or may be integrated to any overall process system. It should be appreciated that ambient temperature water and cold water may be used interchangeably herein unless noted otherwise.

By way of example, the process system 14 may be a semiconductor manufacturing system. The heating system 100, sometimes referred to as a heater 100, may be in fluid connection with the cold water source 12, the hot water source 26, and the process system 14, and may be utilized to heat ultra-pure deionized water to a desired temperature for use in the process system 14. The ambient temperature water source 12 may provide water to the heating system 100 via at least one flow path 20, and the hot water source 26 may provide hot (or heated) water to the heating system 100 via at least one flow path 28. It should be appreciated that the heater 100 or any other heater disclosed herein may utilize either or both of the ambient temperature water source 12 or the hot water source 26. For instance, heater 100 may utilize an ambient temperature source 12 and heater 400 may utilize both the ambient temperature water source 12 and the hot water source 26. Yet in other embodiments, a heater may utilize only the hot water source 26. It should be appreciated that cold water may refer to ambient temperature water, unheated water, or any other temperature of water below the process water temperature. Hot water, or heated water, may refer to water that has been heated as part of a heating process to a temperature above ambient temperature.

As shown in FIG. 1, heated water may flow from the heating system 100 to the process system 14 via at least one flow path 22 and may return to the heating system via at least one flow path 24. Each of the flow paths 20, 22, 24, and 28 may comprise, for example, piping, tubing, valves, pressure relief components, pumps, sensors, flow meters, or any other suitable mechanism for fluid transport. Each flow path may comprise one or more physical flow paths for fluid transport without deviating from the scope of the disclosure. A control system may be integrated with any or all components of the system 10 to facilitate control and monitoring of the system 10.

Although illustrated as singular components or systems, it should be appreciated that system 10 may include one or more ambient water sources 12, one or more hot water sources 26, one or more heating systems 100, and one or more process systems 14. By way of example, a system 10 may comprise two ambient water sources 12, two hot water sources 26, two heating systems 100, and 4 process systems 14. Similarly, the process system 14 may include one or more system components or process tools 16 that utilize a flow of ultra-pure or deionized water during operation.

It should be appreciated that the flow of ultra-pure deionized water between the heater 100 and the process system 14 may be a recirculating closed loop system. In other words, ultra-pure deionized water may continuously flow from the heater 100 to the process system via flow path 22, and the water may return to the heater 100 via flow path 24. The flow through flow path 22 and flow path 24 may represent the closed loop system. The ultra-pure deionized water that returns to the heater 100 via return flow path 24 may be unused water that has not be exposed to atmosphere or used by a process tool 16 of the process system 14. In an implementation, water that is used or exposed to atmosphere may not return to the heater 100 via return path 24, and may instead be released to a drain. The ambient water source 12 or the hot water source 26 may be used to replace spent ultra-pure deionized water that may have been used by the process system 14. In other words, the closed loop of the heating system 100 may hold a constant volume of water, which may be maintained using a supply of water from either or both of the ambient temperature source 12 or the hot water source 26.

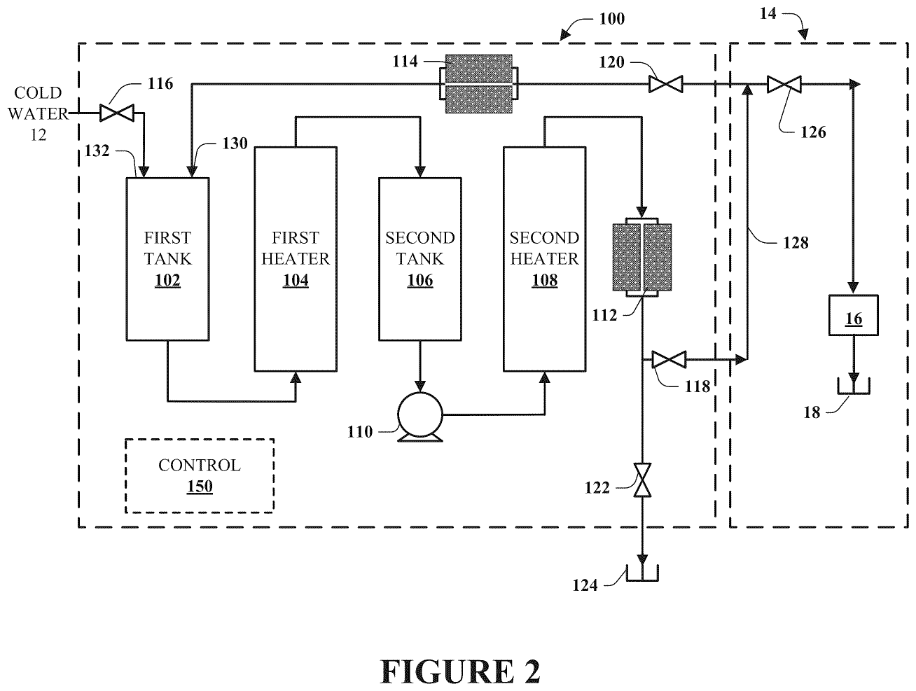

Turing to FIG. 2, an exemplary recirculating heating system 100, or heater 100, is shown. The heater 100 may comprise one or more first tanks 102 (soak tanks), one or more first heaters 104 (bulk heaters), one or more second tanks 106 (bulk tanks), one or more second heaters 108 (trim heaters), one or more pumps 110, one or more first filters 112, and one or more second filters 114. As illustrated in FIG. 2, the heating system comprises one first tank 102 (soak tank), one first heater 104 (bulk heater), one second tank 106 (bulk tank), one second heater 108 (trim heater), one pump 110, one first filter 112, and one second filter 114. The heater 100 utilizes a supply of ambient temperature water supplied through the cold/ambient water source 12.

To facilitate fluid flow to and from the heater 100, various inputs, outputs, valves, piping, or fittings may be utilized. For example, water supply valve 116 may facilitate fluid flow from the ambient water source 12 to a component of the heater 100, such as to the first tank 102. Water outlet valve 118 may facilitate fluid flow from the heater 100 to a process system, such as the process system 14. It should be appreciated that water supplied to the process system 14 may be heated ultra-pure and deionized water for use by various process tools 16 and components of the process system 14. The ultra-pure deionized water may return from the process system 14 to the heater 100 via return valve 120.

As discussed above, the flow of water between the heater 100 and the process system 14 may be a closed loop system that is not exposed to atmosphere, impurities, or that is otherwise spent in the process system 14. The closed loop system may continuously recirculate heated ultra-pure water between the heating system 100 and the process system 14. The recirculated ultra-pure water may be maintained at a desired temperature, pressure, or flow rate for on-demand use by a process tool 16 or component of the process system 14. At least one benefit of a recirculating closed loop system is that heated ultra-pure water is available to the process system 14 as needed in less amounts of time compared to conventional systems. In other words, the tools from process system 14 may utilize water from the closed loop as needed (e.g., via valve 126), and the water may be already heated to the desired temperature. In a non-recirculating system, heated water may be sent from a heater to a process tool 16 and then to a drain after use. Similar to how homeowners may need to run a faucet of a sink or a tub for a period of time until the water becomes warm, non-recirculating systems may require extra time to flush out fluid lines of cold water before the hot water reaches the process system and components. Other systems may bleed a small amount of water through a single pass system to maintain temperature within the line. This can result in wasted time, wasted energy, and inaccurate water temperatures. A closed loop, recirculating system may provide heated water, on-demand, to the process system.

The heater 100 described herein may utilize a closed loop of recirculating hot water that circulates through the process system 14 and/or near process tools 16 that require the hot water, thereby providing hot water to process tools 16 on-demand and in less time than conventional non-recirculating systems. Water that is used by one or more process tools 16 may be discarded via drain 18, for example. In other examples, the water used by the process tools 16 may be recirculated back into the closed loop system.

The heating system 100 may be a single stage or multiple stage heating system. As illustrated in FIG. 2, the heating system 100 may be a two stage heating system. In this implementation, the first tank 102 may be located upstream, at the suction side of the first heater 104 such that the first heater 104 (first stage heater 104) heats fluid or water from the first tank 102. The second tank 106 may be located downstream of the first heater 104, at the outlet side of the first heater 104. In this manner, water heated from the first heater 104 may flow into the second tank 106. The pump 110 may be located at the outlet of the second tank 106 and at the suction side of the second heater 108 (second stage heater 108). The configuration of the second tank 106, the second heater 108, and the pump 110 may promote dampening of the temperature fluctuation induced by deionized water usage by the end user. It should be appreciated that one or more pumps 110 may be used and that location of the pumps may be configured according to system requirements. For instance, the pump 110 may promote fluid flow through the heating system 100 as well as through the closed loop system to the process system 14. In other configurations, additional pumps may be used to circulate the fluid or water through the closed loop at locations within the heater 100 or outside of the heater 100.

As described above, the first heating stage may be accomplished using the first heater 104 and the second heating stage may be accomplished using the second heater 108. In an implementation, the first tank 102 may be filed with or maintained with a volume of water via an input 130 from the closed loop and via an input 132 from the cold water source 12. The first tank 102 may serve to combine water from at least the cold water source 12 and the returned recirculation water from the closed loop. Water may flow from the first tank 102 to the first heater 104 where it is heated to a first temperature (e.g., pre-heat temperature). Once the water passes through the first heater 104, it may pass to the second tank 106. From the second tank 106, the water may flow through the pump 110 to the second heater 108 wherein the water is heated to a second temperature (e.g., final temperature). The first heater 104 may do a majority of the heating to heat the water from the first tank 102 to a pre-heat temperature, and the second heater 108 may bring the pre-heated water from the second tank 106 close to a final temperature (final setpoint). In this manner, the first heater 104 can accomplish most of the heating and the second heater 108 can accomplish more precise heating to the final temperature. As explained above, process systems such as those for semiconductor manufacturing often require heated fluid or water that is within strict temperature and pressure thresholds. It can often be difficult to heat water or fluid from a low temperature to a high temperature with a high degree of accuracy. Utilizing multiple heating stages may make the process more efficient and more easily accomplished. For example, the heating system 100 may be able to maintain the final temperature of the deionized water provided to an end user within <0.3° C. of a specified final setpoint temperature.

As described above, the first tank 102 (or pressure vessel 102 or soak tank 102) may enable the mixing of the returned hot deionized water (e.g., from return valve 120 via the input 130) with the cold supply of deionized water (e.g., from cold water source 12 via the input 132). The mixing of the hot and cold deionized water in the first tank 102 may have various useful effects. For example, the temperature of the hot deionized water may be reduced by the cold deionized water that may be in the first tank 102, thus eliminating the need to dump the hot returned deionized water down a drain. As another example, the mixing of the hot and cold deionized water in the first tank 102 will also cause an increase in temperature of the cold deionized water, which may help the first stage heater 104 meet the pre-heat temperature more quickly than if the hot deionized water were not present in the first tank 102. In certain embodiments, the heater 100 may selectively control the amount of hot return water via the input 130 and the amount of cold water via the input 132 that is sent or mixed into the first tank 102 to achieve desired heating setpoints.

The heater 100 may also include at least one flow control device for controlling an amount or a flow rate of cold water from the cold water source 12 that is sent to the first tank 102. The flow controller may be any suitable flow controller, such as an electronic flow controller that may integrate with the control system 150.

The first heater 104 and/or the second heater 108 may be a heat exchanger and may include one or more heating elements that each comprise a thin film heater on a quartz substrate. The thin film heater on a quartz substrate may facilitate quick, accurate, and efficient heating of the water. Although a two-stage heating system 100 is disclosed herein, single stage a three-stage, four-stage, or similar heating system may be utilized in a similar manner without deviating from the scope of this disclosure.

The heating system 100 may comprise various filters throughout the system, such as filters 112 and 114. The filter 112 may be located downstream of the second stage heater 108 and may remove particles and any unwanted containments of the fluid. The filter 114 may be located in a location upstream of the first tank 102, such as downstream of the return valve 120 and upstream of the return input 130. Similar to the filter 112, the filter 114 may remove particles and any unwanted containments of the fluid. Other filters may be utilized throughout the system at various locations according to fluid system requirements.

By way of example, the ultra-pure deionized water may flow, via closed loop, between the heater 100 and the process system 14. Specifically the water may flow from the first tank 102, the first heater 104, the second tank 106, the pump 110, the second heater 108, the first filter 112, the outlet valve 118, the return valve 120, the second filter 114, and the input 130. After passing through the return valve 120 and the second filter 114, the fluid may flow back into the first tank 102 via the input 130 where it is mixed with other water in the first tank 102. From the first tank 102, the water may, once again, be sent to the first heater 104 for heating. It should be appreciated that the flow path 128 between the outlet valve 118 and the return valve 120 may be closed (e.g., part of the closed loop) and not exposed to atmosphere or contaminants. Although the heated water may flow through the process system 14, via flow path 128, water (or majority of the water) may not be used or exposed to atmosphere. In this example, the unused water that is not exposed to atmosphere is returned to the heater system 100 via the return valve 120 and the input 130.

Additionally, the heating system 100 may comprise a process valve 126 to deliver heated ultra-pure water to a process tool 16 of the process system 14. It should be appreciated that the process tool 16 may be one or many tools, processes, or sub-systems that requires a supply of heated ultra-pure water. There may be one process valve 126 delivering heated water to a single process tool 16 or many process tools 16. In other examples, there may be one or more process valves 126 delivering heated water to one or more process tools 16. The process valve 126 may deliver a portion of the heated water from the closed loop system to one or many tools, processes, or sub-systems. The portion of the heated water that is not routed to the process tool(s) 16 through the process valve 126 may continue to recirculate though the closed loop system (e.g., via flow path 128). One will appreciate that the volume of water in the closed loop system may be sized accordingly such that water may continue to circulate even while process tools 16 are using a portion of the heated water. In other words, the volume of water circulating in the closed loop at any given point may be greater than the volume of water used by the process tools 16. Any water that is used by a process tool 16 or that otherwise leaves the closed loop may be replenished by the cold water source 12 via the input 132 to the first tank 102.

The heating system 100 may also comprise a drain 124 and a drain valve 122. To ensure that water circulating within in the closed loop system is recycled, the heating system 100 may drain an amount of water to the drain 124 at a predetermined or calculated interval or volume. The water may be replaced with water from the cold water source 12. It should be appreciated, however, that the amount of water disposed out of the drain 124 may be a small percentage of the total water within the closed loop of the heating system 100. In other words, most of the water within the closed loop may be recirculated and a small percentage of water may be disposed of through the drain 124. The heating system 100 may calculate, in real time, or may be pre-configured to drain a percentage of water through the drain 124 per the requirements of the system.

At least one benefit to draining an amount of water from the heating system 100 via the drain 124 is to maintain purity standards. For instance, a small amount of impurities may be absorbed into ultra-pure or deionized water at any point in the process, such as through piping, tanks, or heat exchangers. By draining a percentage of water in the closed loop at regular or calculated intervals, the system can ensure that the volume of water in the heating system 100 is kept at suitable purity standards. During periods when process tools 16 are using a portion of the water, draining a portion of water through the drain 124 may not be necessary or less draining may be required. But, during periods when no water is being used by the process system 14, draining a portion of the water through the drain 124 may be needed to ensure purity standards for the water. It should be appreciated that the heating system 100 or the control system 150 may calculate an amount of water to drain in order to maintain the water at suitable purity standards.

In other examples, a portion of the water may be drained via the drain 124 when the temperature of the water in the closed loop is too high or higher than desired. Draining a portion of water from the closed loop via the drain 124 may lower the temperature of the water in the closed loop when the volume of water is replaced with water from the cold water source 12. It may also help ensure that temperatures do not rise higher than desired. Moreover, water may be disposed out of the drain 124 during periods of overpressure in the closed loop. It should be appreciated that a volume of water may need to be disposed of out of the drain 124 to make room for cold water from the cold water source 12. In other words, removal of water from the closed loop may be necessary to prevent over-pressurizing the closed loop.

In an embodiment, the heater 100 may include a control system 150. The control system 150 may control all or some aspects of heating system 100 or the system 10. In some instances, the control system 150 may facilitate temperature settings, flow settings, and pressure settings of the heating system 100. The control system 150 may also monitor the heating system for performance, errors, faults, damage, and the like. In other examples, the control system 150 may also manage the incoming supply pressure to both keep the pressure of the loop at a set pressure, as well as to allow the deionized water to continue to recirculate through the closed loop fluid system. The control system may operate in connection with, and communicate, with various fluid system components to monitor, and control parameters of the heating system 100. Such fluid system components may include, but are not limited to, pressure gauges, flow meters, temperature gauges, differential pressure gauges, demineralizers, thermometers, thermostats, and thermistors.

The control system 150 may be a programmable logic controller (PLC). The PLC may communicate with other control systems or other components to control desired features of the system 10 or heating system 100. The control system 150 may be dedicated to, and part of, the heating system 100 such that the control system communicates with a larger location-wide control system. In other words, the heating system 100 may be a turnkey solution with its own dedicated control system 150 that may be integrated with a larger control system. In other implementations, however, the control system 150 (or PLC or the heating system), may be fully integrated with a larger location-wide control system. It should be appreciated that the integration and control of the heating system 100 can be accomplished in any way, with any suitable number of control systems, PLCs, networks, or components, without deviating from the scope of this disclosure.

The control system 150 may control the two stage heating of the heater 100. In an example, various setpoints and thresholds may be utilized to control the heating of the water. A first temperature setpoint for a pre-heat temperature may be configured. The first setpoint may represent the desired temperature for the water exiting the first heater 104. The first setpoint may also feature a tolerance or temperature threshold in which the control system 150 may operate. A second temperature setpoint for a final temperature may also be configured. The second setpoint may represent the desired temperature for the water exiting the second heater 108. The second setpoint may also feature a tolerance or temperature threshold in which the control system 150 may operate. In an implementation, the second temperature setpoint is greater than the first temperature setpoint and the temperature threshold for the second temperature setpoint is narrower than the first temperature threshold. The process tools 16 may operate at a temperate at or near the final temperature setpoint.

The control system 150 may accept inputs from a user designating the first or the second temperature setpoints and thresholds. Alternatively, the control system 150 may calculate the first temperature setpoint and thresholds based on the desired final temperature setpoint and/or final temperature thresholds. Similarly, the control system 150 may calculate any of the temperature setpoints or thresholds automatically based on communicated temperature requirements of the process system 14.

The control system 150 may also control an amount of water sent to the first tank 102 via the cold water supply 12. The control system 150 may also control a flow rate of water sent to the first tank 102 via the cold water supply 12 using at least one flow controller. In other words, the control system 150 may calculate an amount of cold water that is required to achieve the desired first temperature or the second temperature setpoint. This calculation may take into account numerous other variables, including, but not limited to, the temperature, quantity, and flow rate of the recirculated water returning from the return valve 120 and the temperature and amount of water currently within the first tank 102 or the second tank 106. The control system 150 may also take into account other variables when making this calculation such as the current amount of water being used by the process system 14 or an amount of water being disposed of through the drain 124 or the drain 18. Additionally, the control system 150 may also take into account other variables when making this calculation such as the temperature of the water exiting the first heater 104 or the second heater 108, the temperature of the water entering the first tank 102 from the return valve 120, or the temperature of the water at any other location in the closed loop system.

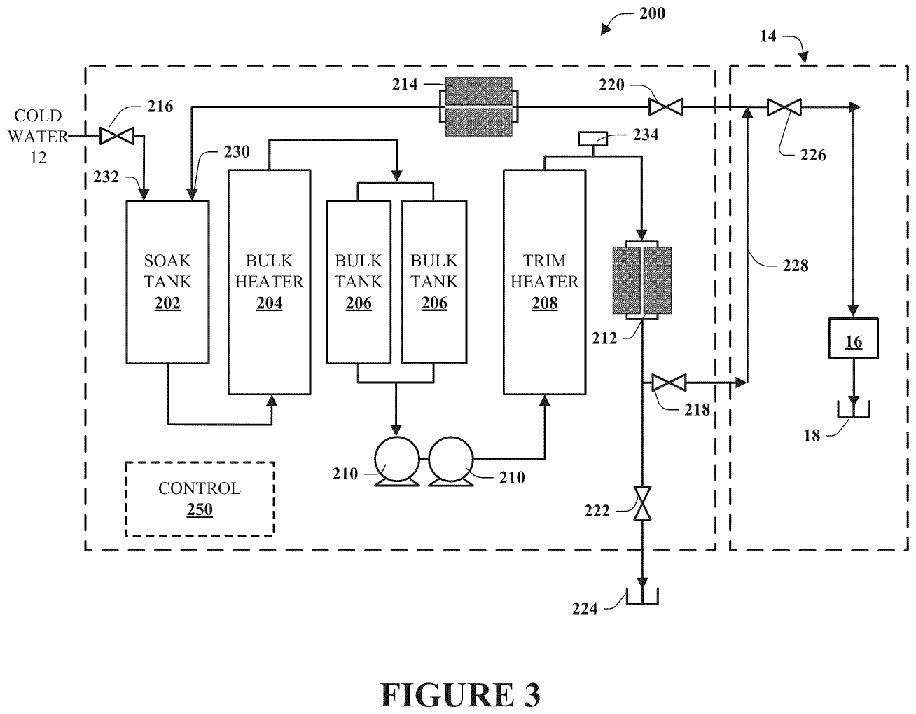

Turning to FIG. 3, an exemplary implementation a heating system 200 is shown. The heating system 200 may be similar to heating system 100 in all ways except as noted herein. That is, the heater 200 may comprise a first tank 202 (soak tank 202), a first heater 204 (bulk heater 204), two second tanks 206 (bulk tanks 206), two pumps 210, one second heater 208 (trim heater 208), one or more first filters 212, one or more second filters 214, and at least one temperature sensor or thermocouple 234. The heater 200 may utilize a supply of ambient temperature water supplied through the cold/ambient water source 12. The thermocouple 234 may measure a temperature of the water leaving the trim heater 208 (e.g., the final temperature).

As discussed above, the heating system 200 may be similar to and operate in a similar manner to the heating system 100, except that the heating system 200 may comprise two bulk tanks 206 rather than the single second tank 106 disclosed in heating system 100. The bulk tanks 206 may be arranged in parallel or series configuration, and although two bulk tanks 206 are illustrated, any number of bulk tanks 206 may be used. The heating system 200 may also utilize two fluid pumps 210 rather than a single pump. The soak tank 202 volume may be equal to or less than the bulk tank 206 volume. For example, the soak tank 202 may hold six (6) liters of fluid and each bulk tank 206 may hold 27.5 liters of fluid (total 55 liters). The tanks may also be sized greater than or less than the example volumes illustrated herein.

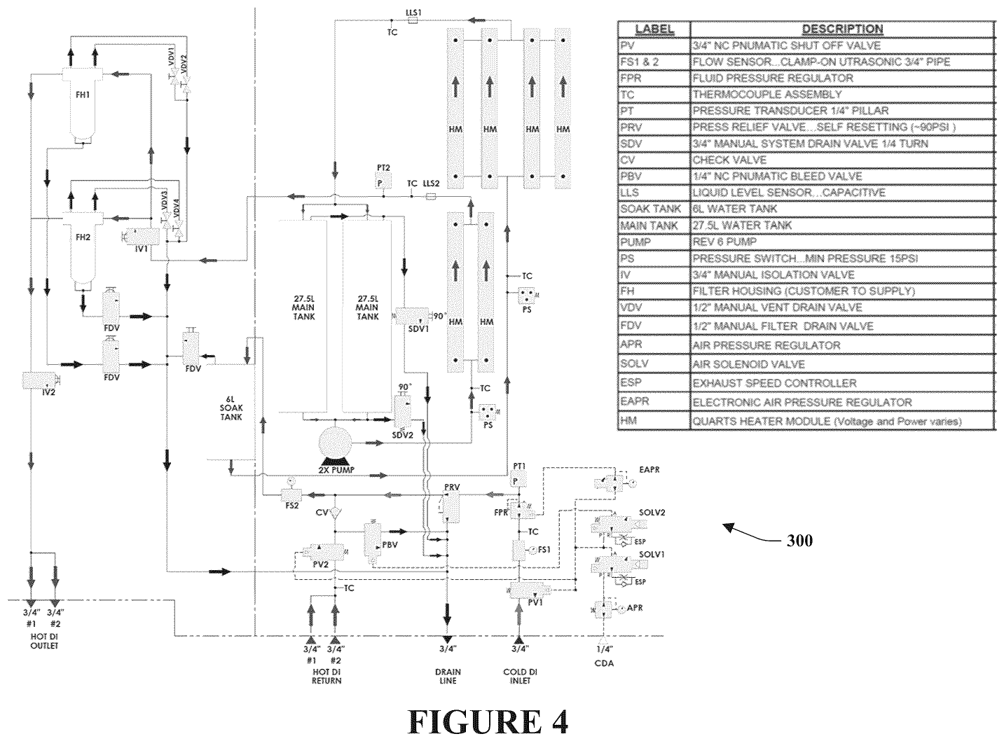

Turning to FIG. 4, an exemplary implementation of a piping and instrumentation diagram of a heating system 300 is shown. The heating system 300 may be similar to and operate in a manner similar to heating systems 100 and 200 in all ways except as noted herein.

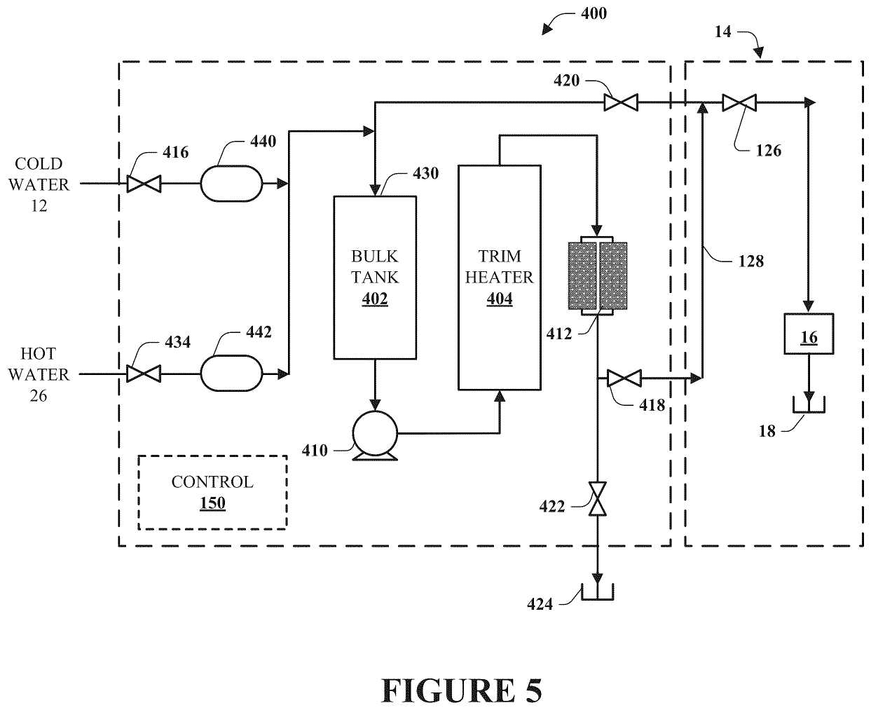

Turning to FIG. 5, an exemplary implementation of a heating system 400 is shown. The heating system 400 may be similar to and operate in a manner similar to heating systems 100, 200, and 300 in all ways except as noted herein. The heating system 400 may comprise a bulk tank 402, a pump 410, a trim heater 404, and a first filter 412. In this implementation, the heating system 400 may be a dual input, single stage recirculating heating system that combines cold water and hot water in the bulk tank 402 prior to flowing to the heating elements.

To facilitate fluid flow to and from the heater 400, various inputs, outputs, valves, piping, or fittings may be utilized. For example, water supply valve 416 may facilitate fluid flow from the ambient water source 12 to the bulk tank 402, and the water supply valve 434 may facilitate fluid flow from the hot water source 26 to the bulk tank 402. Water outlet valve 418 may facilitate fluid flow from the heater 400 to a process system, such as the process system 14. It should be appreciated that water supplied to the process system 14 may be heated ultra-pure and deionized water for use by various process tools 16 and components of the process system 14. The ultra-pure deionized water may return from the process system 14 to the heater 400 via return valve 420.

As discussed above with response to the heater 100, the flow of water between the heater 400 and the process system 14 may be a closed loop system that is not exposed to atmosphere, impurities, or that is otherwise spent in the process system 14. The closed loop system may continuously recirculate heated ultra-pure water between the heating system 400 and the process system 14. The recirculated ultra-pure water may be maintained at a desired temperature, pressure, or flow rate for on-demand use by a process tool 16 or component of the process system 14. Water that is used by one or more process tools 16 may be discarded via drain 18, for example. In other examples, the water used by the process tools 16 may be recirculated back into the closed loop system.

The heating system 400 may be a single stage or multiple stage heating system. As illustrated in FIG. 5, the heating system 400 may be a single stage heating system. The bulk tank 402 may be located at the suction side of the pump 410, and the trim heater 404 may be located downstream of the pump 410. It should be appreciated that one or more pumps 410 may be used and that location of the pumps may be configured according to system requirements. For instance, the pump 410 may promote fluid flow through the heating system 400 as well as through the closed loop system to the process system 14. In other configurations, additional pumps may be used to circulate the fluid or water through the closed loop at locations within the heater 400 or outside of the heater 400.

In an implementation, the bulk tank 402 may be filed with or maintained with a volume of water via an input 430 from the closed loop and/or via the cold water source 12 and/or the hot water source 26. In other words, the bulk tank 402 is filled with water via a combination of recirculated water from the closed loop system and via the cold water source 12 and/or the hot water source 26. By combining calculated amounts of hot water, cold water, and recirculated water, the heating system 400 can ensure that the water inside the bulk tank 402 is at a desired pre-temperature setpoint. Water may flow from the bulk tank 402 to the trim heater 404 where it is heated to a final temperature (final setpoint) for use by a process tool 16 of the process system 14. In this example, the final temperature setpoint may be greater than or equal to the pre-temperature setpoint such that the trim heater 404 is used for fine tuning the temperature of the water. The bulk of the heating may occur outside of the heater 400 and may be accomplished by utilizing hot water from the hot water source 26. For example, the hot water source 26 may be a separate ultra-pure and deionized water heating system featuring suitable heating elements, and the trim heater 404 may be used to incrementally increase the temperature of the water within the bulk tank 402.

As described above, the bulk tank 402 may enable the mixing of the returned hot deionized water (e.g., from return valve 420 via the input 430) with either or both of the cold supply of deionized water (e.g., from cold water source 12) or the hot supply of deionized water (e.g., from the hot water source 26). The mixing of the hot, cold, and recirculated deionized water in the bulk tank 402 may have various useful effects. For example, the temperature of the recirculated deionized water may be reduced by the cold deionized water that may be in the bulk tank 402, thus eliminating the need to dump the hot returned deionized water down a drain. As another example, the mixing of the hot and cold deionized water in the bulk tank 402 will also cause an increase in temperature of the cold deionized water, which may help the trim heater 404 meet the pre-heat temperature more quickly than if the hot deionized water were not present in the bulk tank 402. In certain embodiments, the heater 400 may selectively control the amount of hot water from the hot water source 26 and the amount of cold water from the cold water source 12 that is sent or mixed into the bulk tank 402 to achieve desired heating setpoints. Similarly, the heater 400 may selectively control a flow rate of hot water from the hot water source 26 and a flow rate of cold water from the cold water source 12 that is sent or mixed into the bulk tank 402 to achieve desired heating setpoints.

The heater 400 may also include flow control devices 440 and 442. The flow control device 440 may control an amount or a flow rate of cold water from the cold water source 12 that is sent to the bulk tank 402. The flow control device 442 may control an amount or a flow rate of hot water from the hot water source 26 that is sent to the bulk tank 402. The flow controllers 440 and 442 may be any suitable flow controller, such as an electronic flow controller that may integrate with the control system 450.

Similar to the heater 100, the trim heater 404 may be a heat exchanger and may include one or more heating elements that each comprise a thin film heater on a quartz substrate. The thin film heater on a quartz substrate may facilitate quick, accurate, and efficient heating of the water. Although a single-stage heating system 400 is disclosed herein, two-stage a three-stage, four-stage, or similar heating system may be utilized in a similar manner without deviating from the scope of this disclosure.

The heating system 400 may comprise various filters throughout the system, such as the filter 412. The filter 412 may be located downstream of the trim heater 404 and it may remove particles and any unwanted containments of the fluid. There may also be a filter located upstream of the bulk tank 402, such as downstream of the return valve 420 and upstream of the return input 430. Other filters may be utilized throughout the system at various locations according to fluid system requirements.

By way of example, the ultra-pure deionized water may flow, via closed loop, between the heater 400 and the process system 14. Specifically the water may flow from the bulk tank 402, the pump 410, the trim heater 404, the first filter 412, the outlet valve 418, the return valve 420, and the return water input 430. After passing through the return valve 420, the fluid may flow back into the bulk tank 402 via the input 430 where it is mixed with other water from within the bulk tank 402. From the bulk tank 402, the water may, once again, be sent to the trim heater 404 for heating. It should be appreciated that the flow path 428 between the outlet valve 418 and the return valve 420 may be closed (e.g., part of the closed loop) and not exposed to atmosphere or contaminants. Although the heated water may flow through the process system 14, via flow path 428, water (or majority of the water) may not be used or exposed to atmosphere. In this example, the unused water that is not exposed to atmosphere is returned to the heater system 400 via the return valve 420 and the input 430.

Similar to the system 100, the heating system 400 may comprise a process valve 426 to deliver heated ultra-pure water to a process tool 16 of the process system 14. It should be appreciated that the process tool 16 may be one or many tools, processes, or sub-systems that requires a supply of heated ultra-pure water. There may be one process valve 426 delivering heated water to a single process tool 16 or many process tools 16. In other examples, there may be one or more process valves 426 delivering heated water to one or more process tools 16. The process valve 426 may deliver a portion of the heated water from the closed loop system to one or many tools, processes, or sub-systems. The portion of the heated water that is not routed to the process tool(s) 16 through the process valve 426 may continue to recirculate though the closed loop system (e.g., via flow path 428). One will appreciate that the volume of water in the closed loop system may be sized accordingly such that water may continue to circulate even while process tools 16 are using a portion of the heated water. In other words, the volume of water circulating in the closed loop at any given point may be greater than the volume of water used by the process tools 16. Any water that is used by a process tool 16 or that otherwise leaves the closed loop may be replenished by the cold water source 12 or the hot water source 26.

The heating system 400 may also comprise a drain 424 and a drain valve 422. To ensure that water circulating within in the closed loop system is recycled, the heating system 400 may drain an amount of water to the drain 424 at a predetermined or calculated interval or volume. The water may be replaced with cold water from the cold water source 12, hot water from the hot water source 26, or a combination of hot and cold water the cold water source 12 and the hot water source 26. It should be appreciated, however, that the amount of water disposed out of the drain 424 may be a small percentage of the total water within the closed loop of the heating system 400. In other words, most of the water within the closed loop may be recirculated and a small percentage of water may be disposed of through the drain 424. The heating system 400 may calculate, in real time, or may be pre-configured to drain a percentage of water through the drain 424 per the requirements of the system.

At least one benefit to draining an amount of water from the heating system 400 via the drain 424 is to maintain purity standards. For instance, a small amount of impurities may be absorbed into ultra-pure or deionized water at any point in the process, such as through piping, tanks, or heat exchangers. By draining a percentage of water in the closed loop at regular or calculated intervals, the system can ensure that the volume of water in the heating system 400 is kept at suitable purity standards. During periods when process tools 16 are using a portion of the water, draining a portion of water through the drain 424 may not be necessary or less draining may be required. But, during periods when no water is being used by the process system 14, draining a portion of the water through the drain 424 may be needed to ensure purity standards for the water. It should be appreciated that the heating system 400 or the control system 450 may calculate an amount of water to drain in order to maintain the water at suitable purity standards.

In other examples, a portion of the water may be drained via the drain 424 when the temperature of the water in the closed loop is too high or higher than desired. Draining a portion of water from the closed loop via the drain 424 may lower the temperature of the water in closed loop when the volume of water is replaced with water from the cold water source 12. It may also help ensure that temperatures do not rise higher than desired. Moreover, water may be disposed out of the drain 424 during periods of overpressure in the closed loop. It should be appreciated that a volume of water may need to be disposed of out of the drain 424 to make room for cold water from the cold water source 12 or hot water from the hot water source 26. In other words, removal of water from the closed loop may be necessary to prevent over-pressurizing the closed loop.

Similar to the heater 100, the heater 400 may include a control system 450. The control system 450 may control all or some aspects of heating system 400 or the system 10. In some instances, the control system 450 may facilitate temperature settings, flow settings, and pressure settings of the heating system 400. The control system 450 may also monitor the heating system for performance, errors, faults, damage, and the like. In other examples, the control system 450 may also manage the incoming supply pressure to both keep the pressure of the loop at a set pressure, as well as to allow the deionized water to continue to recirculate through the closed loop fluid system. The control system may operate in connection with, and communicate, with various fluid system components to monitor, and control parameters of the heating system 400. Such fluid system components may include, but are not limited to, pressure gauges, flow meters, temperature gauges, differential pressure gauges, demineralizers, thermometers, thermostats, and thermistors.

The control system 450 may be a programmable logic controller (PLC). The PLC may communicate with other control systems or other components to control desired features of the system 10 or heating system 400. The control system 450 may be dedicated to, and part of, the heating system 400 such that the control system communicates with a larger location-wide control system. In other words, the heating system 400 may be a turnkey solution with its own dedicated control system 450 that may be integrated with a larger control system. In other implementations, however, the control system 450 (or PLC or the heating system), may be fully integrated with a larger location-wide control system. It should be appreciated that the integration and control of the heating system 400 can be accomplished in any way, with any suitable number of control systems, PLCs, networks, or components, without deviating from the scope of this disclosure.

In an example, various setpoints and thresholds may be utilized to control the heating of the water. A first temperature setpoint for a pre-heat temperature may be configured. The first setpoint may represent the desired temperature for the water in the bulk tank 402. The first setpoint may also feature a tolerance or temperature threshold in which the control system 450 may operate. A second temperature setpoint for a final temperature may also be configured. The second setpoint may represent the desired temperature for the water exiting the trim heater 404. The second setpoint may also feature a tolerance or temperature threshold in which the control system 450 may operate. In an implementation, the second temperature setpoint is greater than the first temperature setpoint and the temperature threshold for the second temperature setpoint is narrower than the first temperature threshold.

The control system 450 may accept inputs from a user designating the first or the second temperature setpoints and thresholds. Alternatively, the control system 450 may calculate the first temperature setpoint and thresholds based on the desired final temperature setpoint and/or final temperature thresholds. Similarly, the control system 450 may calculate any of the temperature setpoints or thresholds automatically based on communicated temperature requirements of the process system 14.

The control system 450 may also control an amount of water sent to the bulk tank 402 via the cold water supply 12 and/or the hot water supply 26. The control system 450 may also control a flow rate of water sent to the bulk tank 402 via the cold water supply 12 and/or the hot water supply 26. In other words, the control system 450 may calculate an amount of cold water and/or hot water that is required to achieve the desired first temperature within the bulk tank 402. This calculation may take into account numerous variables, including, but not limited to, the temperature, quantity, and flow rate of the recirculated water returning from the return valve 420 and the temperature and amount of water currently within the bulk tank 402. The control system 450 may also take into account other variables when making this calculation such as the current amount of water being used by the process system 14 or an amount of water being disposed of through the drain 424. Additionally, the control system 450 may also take into account other variables when making this calculation such as the temperature of the water exiting the trim heater 404, the temperature of the water entering the bulk tank 402 from the return valve 420, or the temperature of the water at any other location in the closed loop system. Temperature at any point in the process may be taken using a suitable temperature sensor such as a thermocouple.

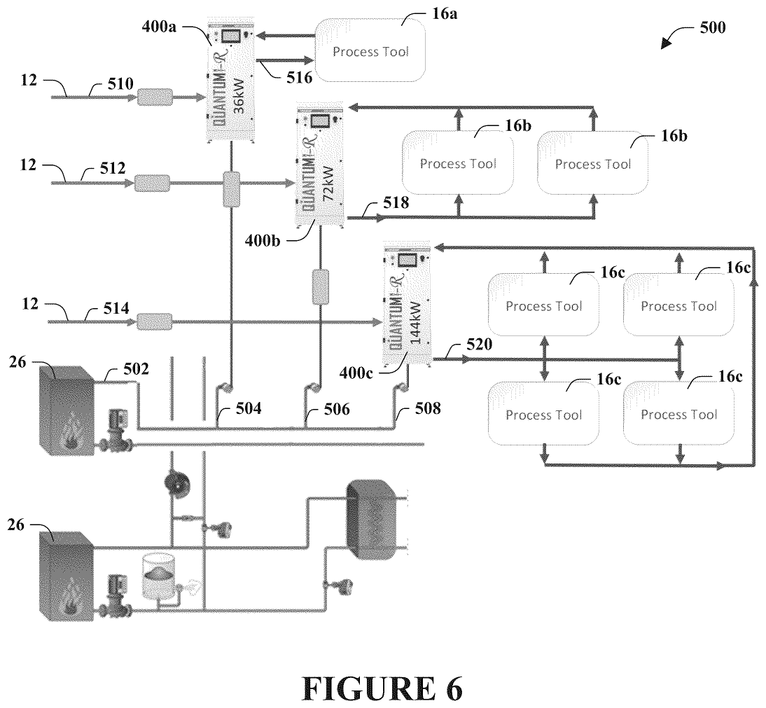

FIG. 6 illustrates an exemplary modular implementation, or point of use (POU) implementation of the heater 400. The modular system 500 may feature one or more heaters 400, one or more process tools 16, one or more hot water sources 26, and one or more cold water sources 12. As illustrated in FIG. 6, the modular system 500 may include one process tool 16a, two process tools 16b, and four process tools 16c. The modular system 500 may include one heater 400a, one heater 400b, and one heater 400c. In this example, process tools 16a, 16b, and 16c may all require different temperatures for ultrapure deionized water. To satisfy this requirement, each heater 400a, 400b, and 400c may be configured to output ultrapure deionized water at different temperatures according to the needs of the process tools. For instance, the heater 400a may output ultrapure water at a first temperature suitable for use by the process tool 16a. The heater 400b may output ultrapure water at a second temperature suitable for use by the process tools 16b. The heater 400c may output ultrapure water at a third temperature suitable for use by the process tools 16c. Moreover, the heater 400a may be a first size capable of handling one process tool 16a. The heater 400b may be a second size capable of handling two process tools 16b. The heater 400c may be a third size capable of handling four process tools 16c. The size of the heaters 400 may refer to a heating capability of the heaters measured in kW, for example.

There are numerous benefits to the modular system 500 disclosed herein. For instance, each heater 400 may integrate with existing hot and cold water sources 12 and 26 to achieve desired heating characteristics. The term “existing” may refer to legacy systems or cold water or hot water supplies in an existing process system or environment separate from the heaters 400. The temperature of the cold water from the cold water source 12 may be a first temperature, and the temperature of the hot water from the hot water source may be a second temperature 26. However, without heaters 400, there may be no suitable way to provide different water temperatures to each process tool 16 without implementing difficult solutions. Heaters 400a, 400b, and 400c, allow for the input of hot and cold water from the hot and cold water sources 26 and 12 and may increase the temperature of this input by a pre-determined amount to achieve a final temperature setpoint suitable for use by each process tool 16. Each final temperature setpoint may be different for each of the heaters 400a, 400b, and 400c.

In an exemplary implementation, temperatures at locations 510, 512, and 514 of the cold water inputs may be about 20 degrees C. The temperature at location 502 proximate the hot water source 26 may be 75 degrees C. The temperature at location 504 proximate the hot water input for the heater 400a may be 70 degrees C. The temperature at location 506 proximate the hot water input for the heater 400b may be 65 degrees C. The temperature at location 508 proximate the hot water input for the heater 400c may be 60 degrees C. The heater 400a may be configured to output 80 degree C. water to the closed loop at location 516. The heater 400b may be configured to output 70 degree C. water to the closed loop at location 518. The heater 400c may be configured to output 80 degree C. water to the closed loop at location 520. It should be appreciated that without the point of use heaters 400a, 400b, and 400c, the final temperature at the process tools 16a, 16b, and 16c may be undesirable (e.g., too low or too high). Further, because the hot water source 26 is often far away from the process tools 16, maintaining the water temperature to a desired setpoint can be difficult and costly. The heaters 400a, 400b, and 400c may allow for more accurate, faster, and more efficient heating of water for the process tools 16.

In this example, the point of use heaters 400a, 400b, and 400c can be used in conjunction with a central heating system (e.g., hot water source 26). A lower power point of use heater 400a may be used to support an individual process tool 16a. A single higher power heater 400c can support multiple tools 16c. Process temperatures can be increased or decreased at the point of use heaters 400a, 400b, and 400c rather than at the hot water source 26 or cold water source 12. Process temperatures can also be increased or decreased at the point of use heaters 400a, 400b, and 400c much more quickly than compared to the hot water source 26 or cold water source 12. For instance, water in the closed loop heater system 400 may be dumped out of the drain 424 to rapidly cool the water temperate in the closed loop to a desired setpoint. Lowering the temperature of water from the hot water source 26 may take more time and may not be desired. For instance, lowering the temperature of water from the hot water source 26 may lower the water temperature for numerous other process tools that require higher temperature. This is not desired.

Moreover, combining the central heating system with point of use heaters 400a, 400b, and 400c, can help to reduce natural gas consumption by using heaters 400a, 400b, and 400c instead. For instance, the hot water source 26 may heat water using natural gas, and the heaters 400a, 400b, and 400c may heat the water using electricity. Therefore, the system 500 may increase electricity consumption to offset the natural gas decrease, which may be more desirable. Combining the central heating system with point of use heaters 400a, 400b, and 400c can allow for reduced central loop flow rates (e.g., flow rates at locations 502, 504, 506, and 508 by increasing the heating done by heaters 400a, 400b, and 400c, which may increase electricity consumption and decrease natural gas consumption.

In the semiconductor industry, “fab” and “sub-fab” are terms used to describe different parts of the facilities where semiconductor devices are manufactured. Fab (or fabrication) is the main area where semiconductor devices are manufactured. It is usually a highly controlled environment, known as a clean room, where the air quality, temperature, and humidity are strictly regulated to avoid any contamination of the silicon wafers. The fab houses complex and expensive machinery used for processes like lithography, etching, chemical vapor deposition, and physical vapor deposition, which are critical for creating integrated circuits on silicon wafers.

Sub-fab (or sub-fabrication) is an area that supports the fab by housing additional equipment and infrastructure that doesn't need to be in the clean room environment but is essential for the operation of the fab. This includes systems like vacuum pumps, abatement systems to treat waste gases, chemical delivery systems, and utilities such as cooling and exhaust systems. The sub-fab plays a crucial role in ensuring that the fab operates efficiently and safely, managing the backend processes that support the front-end manufacturing in the fab. In typical manufacturing plants, the sub-fab system is located on a different physical level or location (e.g., under) the fabrication environment. The distinction between fab and sub-fab may be important because it helps manage costs and efficiency in semiconductor manufacturing. By keeping only the essential processes and equipment that require a clean room environment in the fabrication environment, and placing support equipment in the sub-fab, manufacturers can optimize space and improve operational dynamics.

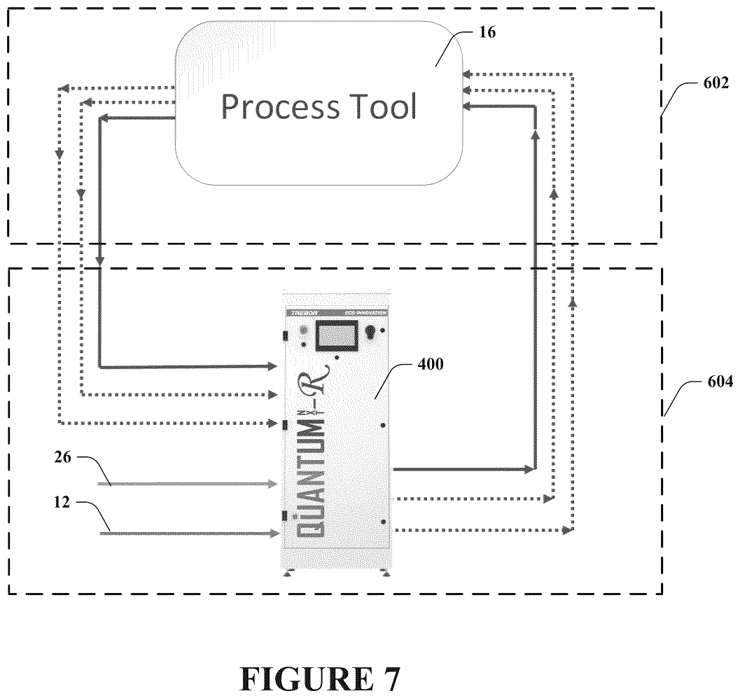

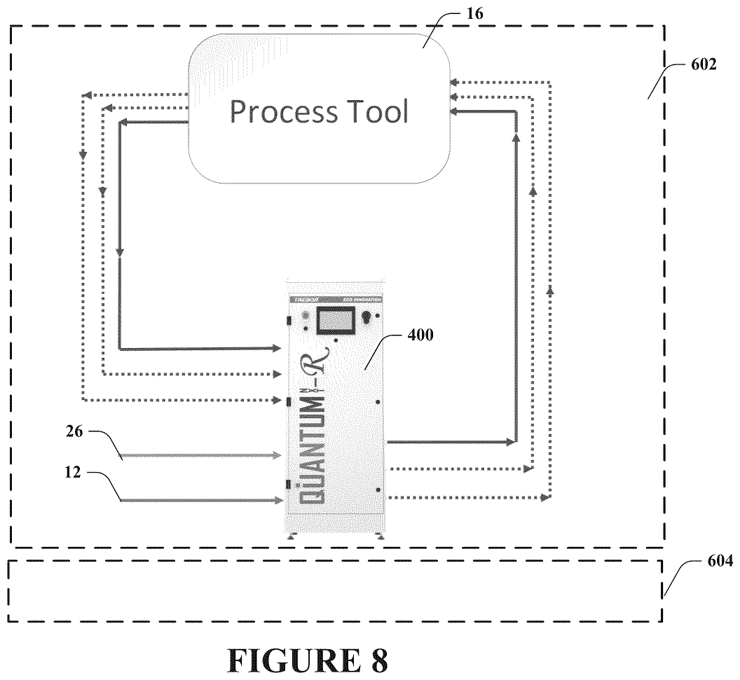

FIGS. 7 and 8 illustrate various exemplary locations that any of the heaters disclosed herein (e.g., heater 100, heater 200, heater 300, heater 400) may be installed. For instance, FIG. 7 illustrates the heater 400 installed at a sub-fab location 604 and FIG. 8 illustrates the heater 400 installed at a fab location 602. The process tool 16 may be located at the fab level 602. It should be appreciated that the heaters 100, 200, 300, and 400 can be installed on either the fab 602 or sub-fab 604 according to the needs of individual systems and components. Installing the heaters in the fab environment 602 may allow for more precise temperature control, faster supply of at-temperature water, more efficient heating, and other improvements. However, installing the heaters at the sub-fab environment 604 may save space on the fab environment 602, which may be beneficial.

Installation of conventional heaters in the sub-fab environment may be difficult due to the piping, pressure, and flow rate constraints. For instance, when the fab 602 and sub-fab 604 environments are located on different elevations, pumping water up or down elevations may be difficult or require additional pumps or energy. In many instances, it may not be possible. It should be appreciated, that the heaters 100, 200, 300, and 400 can be installed on the sub-fab environment 604 and may be able to transport heated water through the closed loop system between the fab 602 and sub-fab 604 environments. This may be beneficial from a flexibility, cost, and space standpoint.

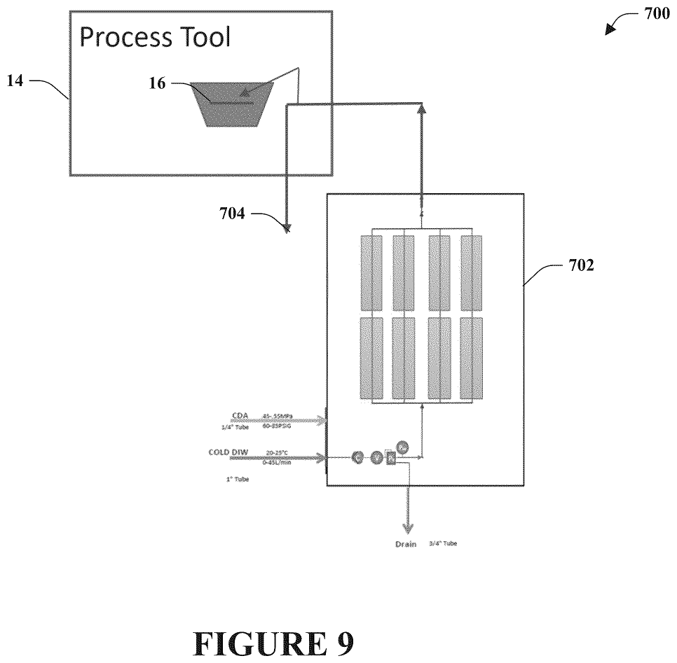

Turning to FIG. 9, a conventional single pass heating system 700 is illustrated. The system 700 includes a heater 702, a process system 14, and a process tool 16. In the system 700, ultra-pure deionized water, after being used in connection with process system 14 and the process tool 16, is sent to a drain 704. As described herein, such an approach is wasteful, and not cost-effective due to at least the expense of replacing the water and having to reheat new water. Moreover, continuous heating of water from ambient (or cold) temperature to the process temperature (final temperature) requires a high amount of energy.

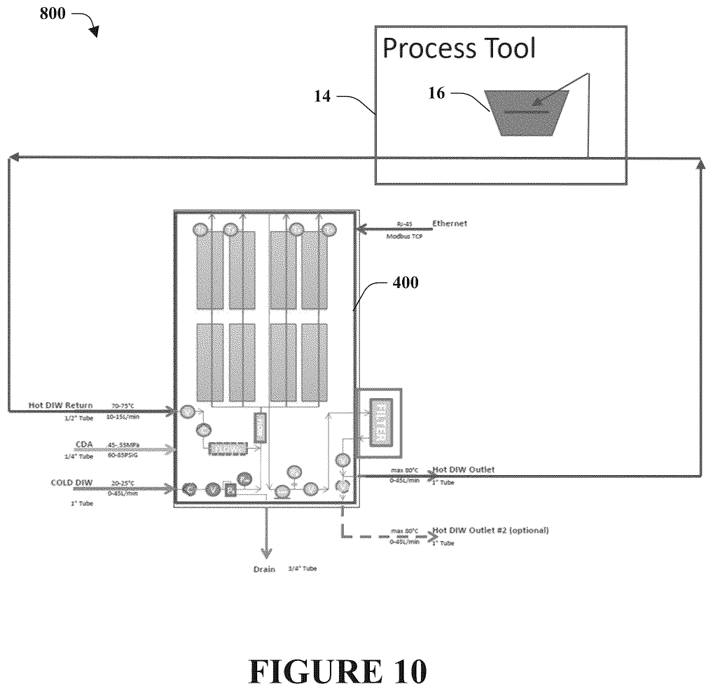

FIG. 10 illustrates a closed loop, recirculating heating system 800 similar to the heating systems 100, 200, 300, and 400. As discussed, use of a closed loop, recirculating heating system may provide numerous advantages over conventional heating systems. Such improvements may be with respect to efficiency, control accuracy, heating times, and the like.

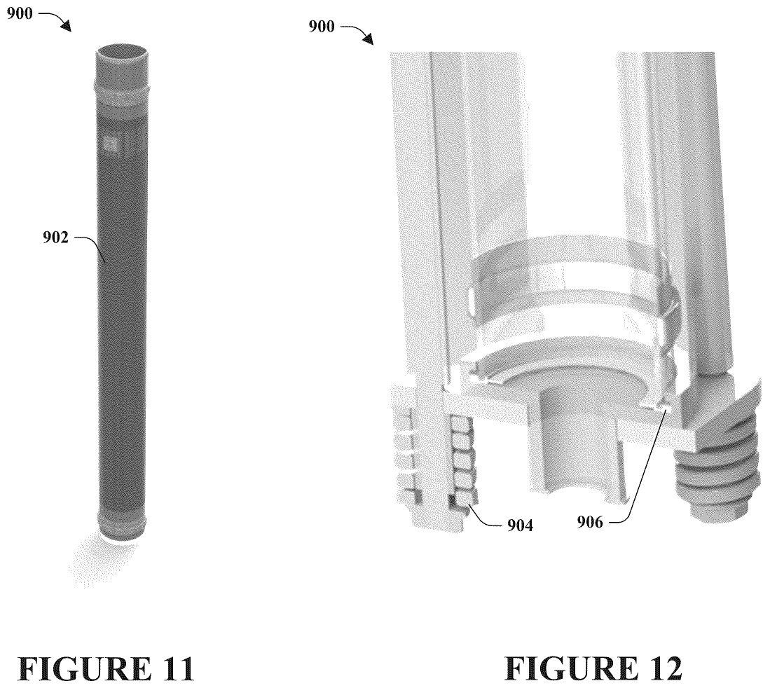

FIGS. 11 and 12 illustrate exemplary embodiments of heating elements for any of the heaters disclosed herein. For instance, the first heater 104, the second heater 108, the bulk heater 204, the trim heater 208, or the trim heater 404 may be a heat exchanger and may include one or more heating elements 900 that each comprise a thin film heater on a quartz substrate 902. The thin film heater on a quartz substrate may facilitate quick, accurate, and efficient heating of the water. Moreover, the vertical orientation of the heating elements 900 (e.g., tubes) may eliminate dead legs and overheating of residual liquid. The thin film resistive media on quartz clement 902 may place the heat in close proximity to the fluid for faster heating. The quartz element may help to ensure that no lamps need replaced and may require no coils known to cause pressure drops. No O-rings may be placed in the fluid path which may eliminate risk of process contamination. Additionally, low thermal mass of the heating elements 900 may allow for fast ramp to temperature and well as a heating efficiency of greater than 90%. Sealing at locations 904 and 906 may be capable of handling thermal shock and thermal cycling without leaks or breaks. The heating elements described herein may be powered using electricity such as three phase electric current.

Further, examples of heating elements that may be used in one or more embodiments of the invention are disclosed in U.S. Pat. Nos. 6,544,583, 6,580,061, 6,663,914, 6,674,053, 6,479,094, and 7,081,602, all of which are incorporated herein in their respective entireties by this reference.

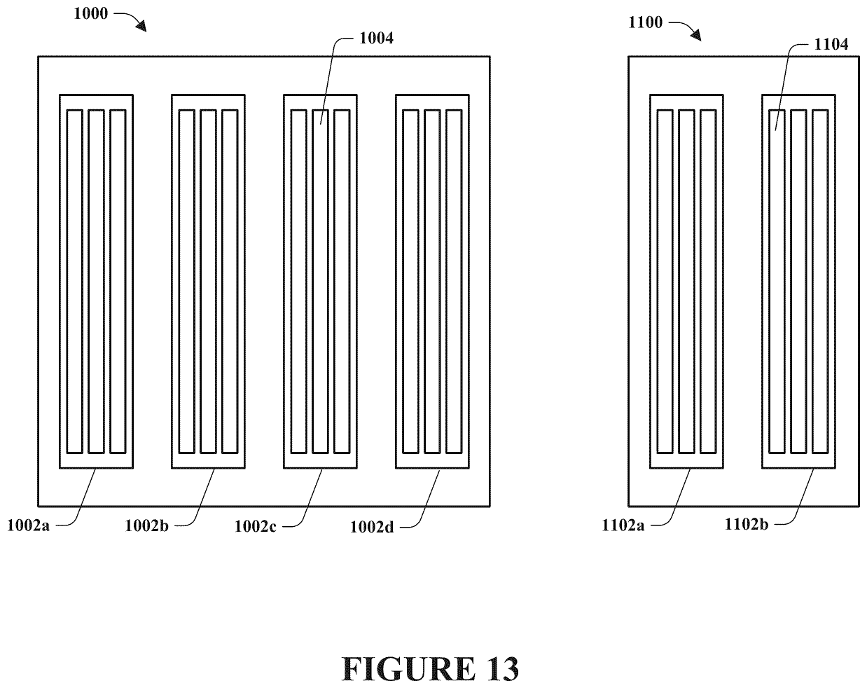

FIG. 13 illustrates exemplary implementations of a bulk heater 1000 and a trim heater 1100. The bulk heater 1000 may comprise a plurality of modules 1002 and the trim heater may comprise a plurality of modules 1102. Each module 1002 or 1102 may comprise a plurality of heating elements (or tubes) 1004 or 1104. As illustrated in the example, the bulk heater 1000 comprises four modules 1002a-d, each having three heating elements 1004. The trim heater 1100 comprises two modules 1002a-b, each having three heating elements 1104. It should be appreciated that any number of heating modules or heating elements may be used for the bulk heater 1000 and the trim heater 1100 depending on heating requirements. Moreover, any of the heating systems disclosed herein may activate or deactivate modules 1002 or 1102 on an individual basis to achieve desired heating characteristics.

By way of example, each heating element 1004 or 1104 may only provide a certain amount of power or heat. Therefore, more heating elements 1004 or 1104 or modules 1002 or 1102 may be required to heat a greater volume of water and/or to heat a volume of water a greater temperature amount in a certain timeframe. In certain implementations, power produced by the heating elements 1004 or 1104 or modules 1002 or 1102 may be calculated using the following equation, where P is power in kW, F is flowrate in liters per minute, ΔT is change in temperature in degrees Celsius, and the value 14.34 is the conversion constant.

P=F*ΔT° C)/14.34

Any of the systems disclosed herein may utilize the disclose equation when calculating a required number of modules per heater to activate to achieve a desired heating or temperature setpoint. The first heater 104, the second heater 108, the bulk heater 204, the trim heater 208, and the trim heater 404 may utilize the disclosed one or more heating elements 1004 or 1104 or one or more modules 1002 or 1102 in a manner similar to the bulk heater 1000 or the trim heater 1100.

As discussed herein, there are numerous benefits associated with the closed loop recirculating heaters described herein when compared to conventional single pass heating systems that use central heating systems. For instance, conventional systems may require additional costs for heat isolation and may still encounter significant thermal loss on hot water as it travels to process tools. Conventional heating systems may also not operate well with changing flow rates or fluctuating demand from a process tool.

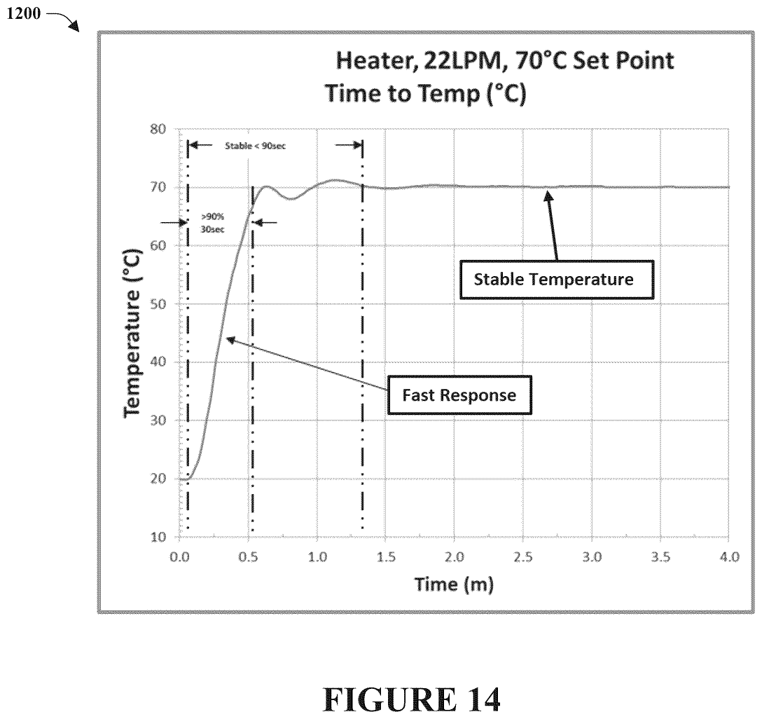

By way of example, FIG. 14 illustrates the temperature of process water (ultra-pure deionized water) as a function of time during a constant flow rate for a single pass heating system such as heater 700. The graph 1200 illustrates that when at a constant flow rate, the temperature of the process water stabilizes after a period of about 1.5 seconds.

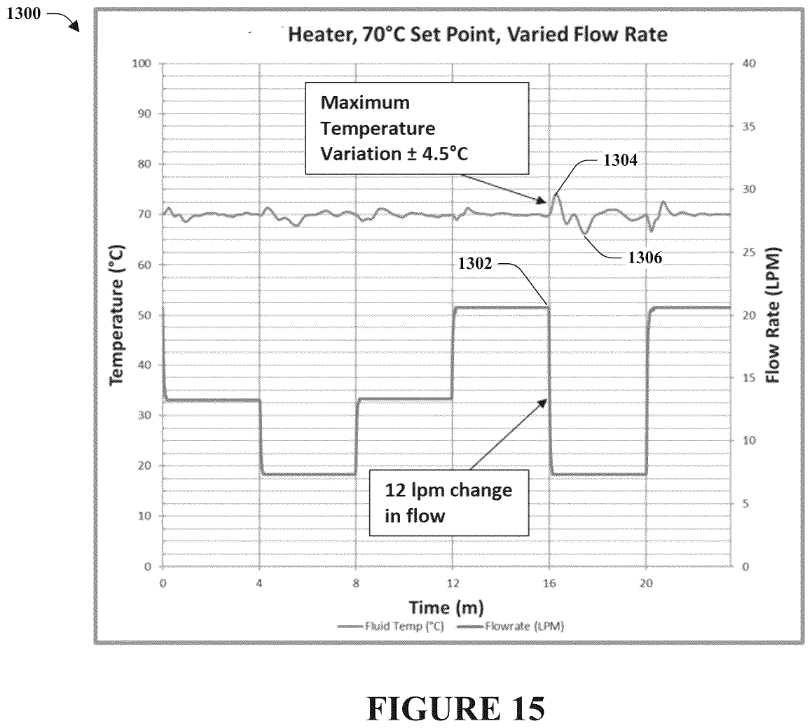

FIG. 15 illustrates the temperature of process water (ultra-pure deionized water) as a function of time during a varied flow rate for a single pass heating system such as heater 700. The graph 1300 illustrates that when there is a change in flow rate 1302, the temperature of the process water may experience a spike 1304 or drop 1306 in temperature. The maximum temperature deviation during a change in flow rate of 12 liters per minute, for example, may lead to a temperature variation of +/−4.5 degrees C. This may be undesirable.

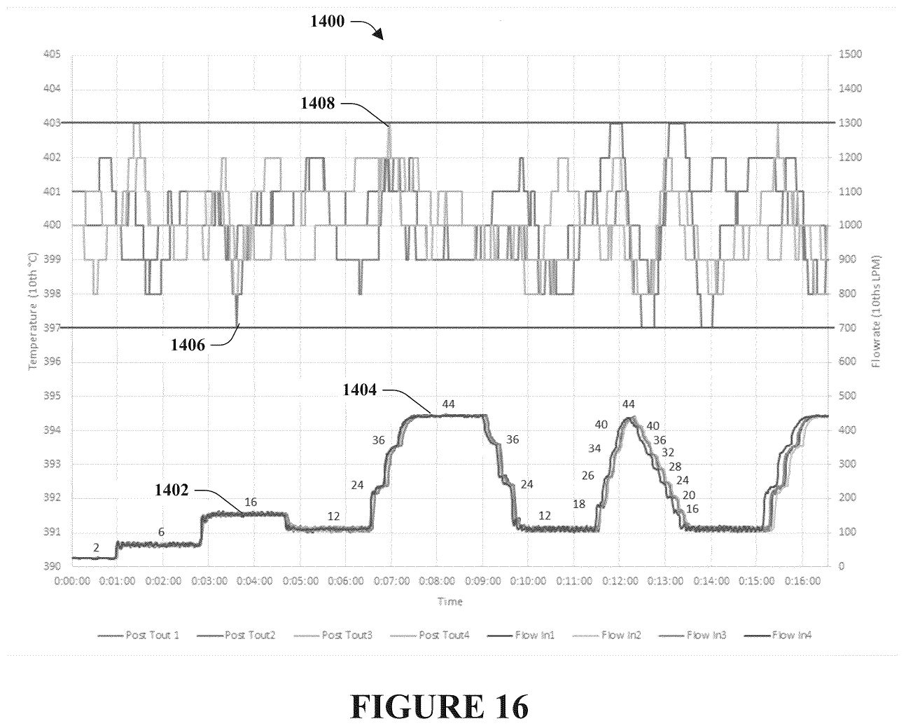

FIG. 16 illustrates the temperature of process water (ultra-pure deionized water) as a function of time during a varied flow rate for a recirculating heating system, such as for the heaters 100, 200, 300, 400, or 800. The graph 1400 illustrates that during changes in flow rate 1402 or 1404, there may be drops 1406 (a minimum temperature) or spikes 1408 (a maximum temperature) for the process water. But, it should be appreciated that the temperature of the process water may be more precise and experience less fluctuations compared to the single pass systems (e.g., FIGS. 14 & 15). Table 1 shown below illustrates various average temperatures, maximum temperatures, minimum temperatures, standard deviations, and actual deviations experienced with four separate changes in flow rates. It should be appreciated that the temperature fluctuation, illustrated at least by the standard deviation of 0.1 C, is less compared to single pass heating systems. In other words, the heaters 100, 200, 300, 400, or 800 may provide more precise temperature for process water that can handle changes in flow rates more efficiently compared to conventional single pass systems.

TABLE 1
Results from FIG. 16

| | Temp | | Temp | | Temp | | Temp | |
|---|---|---|---|---|---|---|---|---|
| | Output for | | Output for | | Output for | | Output for | |
| | Flowrate 1 | | Flowrate 2 | | Flowrate 3 | | Flowrate 4 | |
| Average Temp | 40.0 | C | 40.0 | C | 40.0 | C | 40.0 | C |
| Max Temp | 40.2 | C | 40.3 | C | 40.3 | C | 40.3 | C |
| Min Temp | 39.8 | C | 39.7 | C | 39.8 | C | 39.8 | C |
| STDEV | 0.1 | C | 0.1 | C | 0.1 | C | 0.1 | C |
| Difference+ | 0.2 | C | 0.3 | C | 0.3 | C | 0.3 | C |
| Difference− | −0.2 | C | −0.3 | C | −0.2 | C | −0.2 | C |

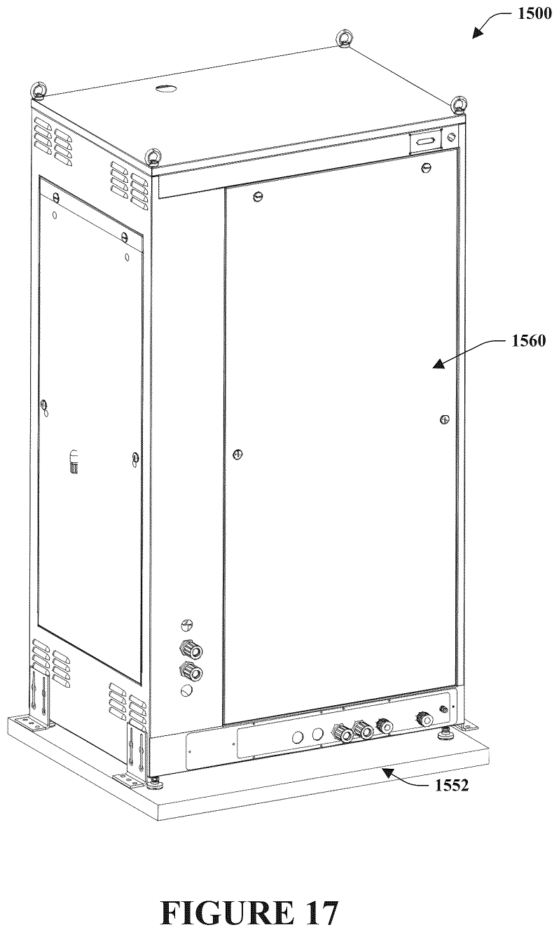

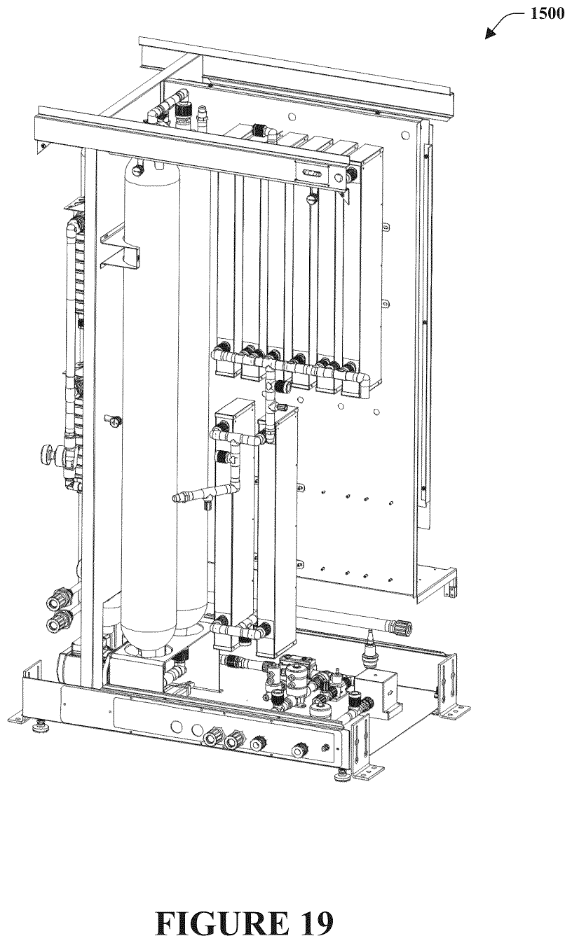

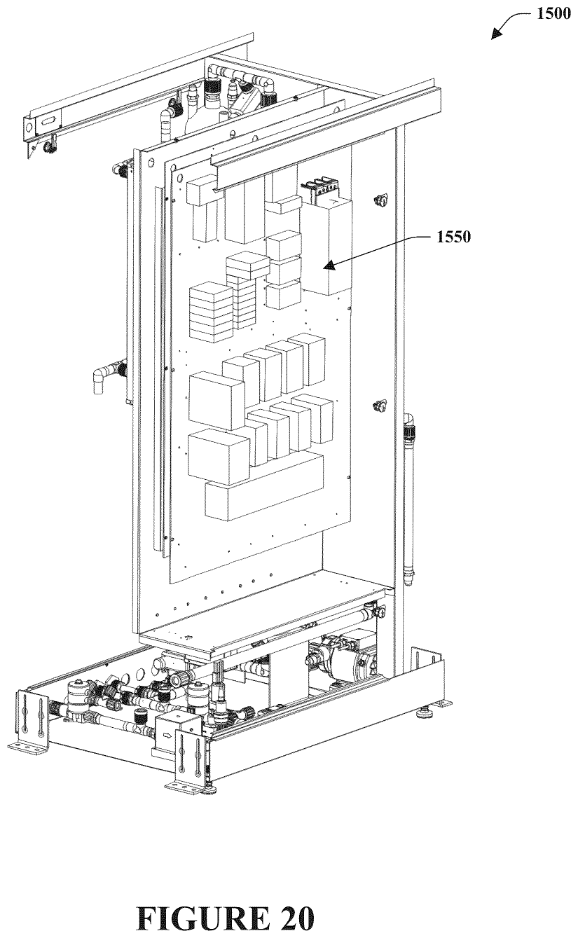

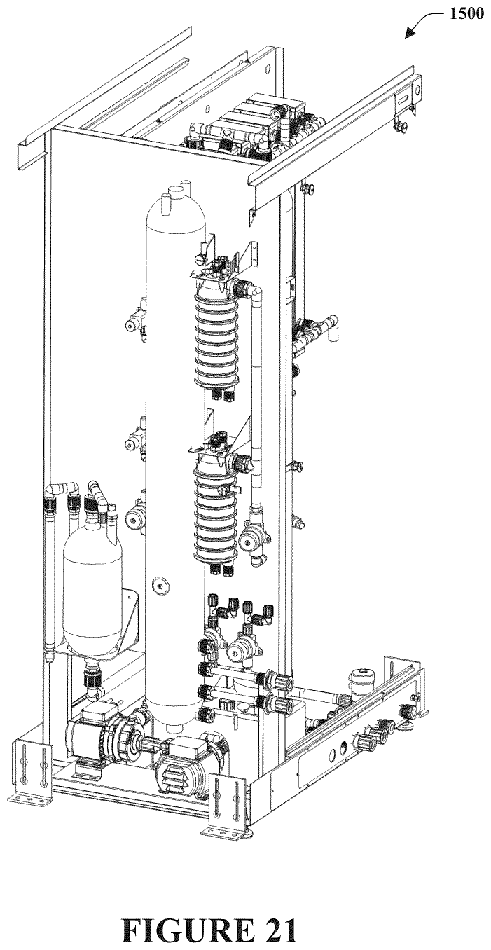

FIGS. 17-21 illustrate an exemplary embodiment of a heater according to the disclosure herein. For example, the heater 1500 may be similar to any of the heaters 100, 200, 300, 400, or 800. That is, the heating system 1500 (also referred to as a heater 1500, a heating device 1500, or heating apparatus 1500) may contain the components of the heating system 100, 200, 300, 400, or 800 and may be enclosed in a single housing or enclosure 1560. In this manner, the heater 1500 may be attached to a skid 1552 for easy transporting and installation. The heater 1500 may take up less space than conventional heating systems and may be installed more easily. In certain applications, a plurality of heaters 1500 may be used as modular system components.

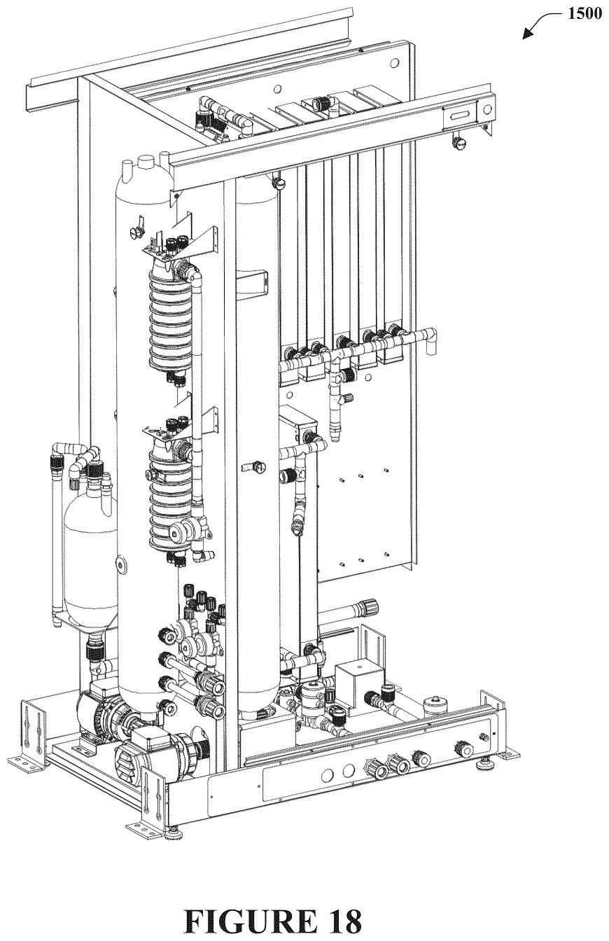

FIGS. 18-21 illustrate an embodiment of the heater 1500 without side panels for case of viewing the internal system components. Like system 100, 200, 300, 400, or 800, the heater 1500 may comprise various tanks, heaters, filters, or pumps. To facilitate fluid flow to and from the heating system 200, various inputs, outputs, valves, piping, or fittings may be utilized. The heater may also comprise a control system 1550, similar to the control system 150. In certain examples, the control system 1550 may be a PLC.

Fluid system components that may be employed in connection with one or more embodiments of the disclosure, such as diaphragm pumps, tanks, heaters, heating elements, filters, pressure regulators, deionizers, suction check valves, and discharge check valves, for example, may be constructed with a variety of components and materials. Such components or material may include, but are not limited to, non-reactive and substantially non-reactive materials, non-metallic and substantially non-metallic materials, rubber, plastics such as polymers, and composites. It should be noted that non-reactive and substantially non-reactive materials embrace a variety of materials, including both metals, such as stainless steel for example, as well as non-metallic materials, such as plastics for example. Examples of the aforementioned polymers include, but are not limited to, perfluoroalkoxy (PFA) and polytetrafluoroethylene (PTFE), which can be machined or otherwise formed into various components, such as pump bodies, pump heads, and diaphragms for example. Fluoroelastomers (FKM), and perfluoroelastomers (FFKM) may also be employed. These materials may or may not be virgin materials. In certain applications, metals such as steel including stainless steel, copper, titanium, brass, nickel, aluminum, and alloys and combinations of any of the foregoing metals, may be used. Examples of such alloys include copper-nickel alloys (CNA), and nickel-copper alloys (NCA).

Examples of systems and methods according to the disclosure are set forth in the following exemplary items:

Item 1. A heating system, comprising:
a first tank;
a first stage heater in fluid communication with and located downstream of the first tank, the first stage heater configured to heat a fluid from the first tank to a first temperature;
a second tank in fluid communication with and located downstream of the first stage heater, the second tank configured to hold at least a portion of the fluid from the first stage heater;
a second stage heater in fluid communication with and located downstream of the second tank, the second stage heater configured to heat at least a portion of the fluid from the second tank to a second temperature higher than the first temperature;
an outlet valve in fluid connection with an outlet of the second stage heater and a first end of a fluid process loop; and
a return valve in fluid connection with a second end of the process fluid loop and an input of the first tank; and
wherein the fluid at the second temperature is configured to exit the heating system at the outlet valve such that the fluid circulates through the fluid process loop and returns back to the first tank through the return valve.

Item 2. The heating system of Item 1, further comprising a filter located between the outlet of the second stage heater and the outlet valve.

Item 3. The heating system of Item 2, wherein the fluid is ultra-pure deionized water.

Item 4. The heating system of Item 1, wherein the fluid process loop is a closed loop such that the fluid in the fluid process loop is not exposed to atmosphere.

Item 5. The heating system of Item 1, wherein the first tank, the first stage heater, the second tank, and the second stage heater are enclosed in a single heating system unit housing.

Item 6. The heating system of Item 1, further comprising a process valve in fluid connection with the fluid process loop, the process valve is configured to route at least a portion of fluid from the fluid process loop to a process tool.

Item 7. The heating system of Item 6, wherein fluid routed to the process tool through the process valve is discarded after use.

Item 8. The heating system of Item 1, further comprising a drain valve located downstream of the outlet of the second stage heater, wherein the heating system is configured to route at least of a portion of the fluid through the drain valve to promote recycling of fluid in the heating system.

Item 9. The heating system of Item 8, wherein an amount of fluid that is routed through the drain valve is calculated based upon at least one characteristic of the heating system.

Item 10. The heating system of Item 1, further comprising a control system configured to control various aspects of the heating system.

Item 11. A method of heating a fluid with a two stage recirculating heating system, the heating system comprising:
a first stage heater;
a second stage heater in fluid communication with and located downstream of the first stage heater;
an outlet valve in fluid connection with an outlet of the second stage heater and a first end of a fluid process loop; and
a return valve in fluid connection with a second end of the process fluid loop and an input of the first stage heater, wherein the method comprises:
   heating a fluid to a first temperature with the first stage heater;
   routing the fluid from the first stage heater to the second stage heater;
   heating the fluid to a second temperature with the second stage heater, the second temperature greater than the first temperature;
   routing the heated fluid from an outlet of the second stage heater to a fluid process loop, the fluid is returned to the first stage heater via the return valve.

Item 12. The method of Item 11, wherein the fluid is ultra-pure deionized water.

Item 13. The method of Item 11, wherein the fluid process loop is a closed loop such that the fluid in the fluid process loop is not exposed to atmosphere.

Item 14. The method of Item 11, wherein the heating system further comprises a process valve in fluid connection with the fluid process loop, the process valve is configured to route at least a portion of fluid from the fluid process loop to a process tool.

Item 15. The method of Item 14, wherein the fluid that is routed to the process tool through the process valve is discarded after use and fluid that is not routed through the process valve is returned to the first stage heater via the return valve.

Item 16. The method of Item 11, wherein the heating system further comprises a drain valve located downstream of the outlet of the second stage heater, wherein the method further comprises routing at least of a portion of the fluid in the fluid process loop through the drain valve to promote recycling of fluid in the heating system.

Item 17. The method of Item 16, wherein an amount of fluid is routed through the drain valve based upon at least one characteristic of the heating system.

Item 18. The method of Item 11, wherein the heating system further comprises a control system configured to control various aspects of the heating system.

Item 19. A heating system, comprising:
a first stage heater configured to heat a fluid to a first temperature;
a second stage heater in fluid communication with and located downstream of the first stage heater, the second stage heater configured to heat at least a portion of the fluid from the first temperature to a second temperature higher than the first temperature;
an outlet valve in fluid connection with an outlet of the second stage heater and a first end of a fluid process loop;
a return valve in fluid connection with a second end of the process fluid loop and an input of the first stage heater; and
a pump located between the first stage heater and the second stage heater, the pump configured to pump the fluid through the process fluid loop,
wherein the fluid is configured to exit the heating system at the outlet valve such that the fluid circulates through the fluid process loop and returns back to the first stage heater via the return valve, the fluid process loop is a closed loop system.

Item 20. The heating system of Item 19, further comprising a process valve in fluid connection with the fluid process loop, the process valve is configured to route at least a portion of fluid from the fluid process loop to a process tool such, the fluid routed through the process valve is sent to a drain after use, and the fluid that is not routed through the process valve is returned to the heating system via the return valve.

Item 21. A heating system, comprising:
a tank with a first input and a second input, the first input configured to accept a flow of water from a first water source and the second input configured to accept a flow of water from a second water source, the tank holding a volume of water at a first temperature;
a heater in fluid communication with and located downstream of the tank, the heater configured to heat at least a portion of the fluid from the tank from the first temperature to a second temperature higher than the first temperature;
an outlet valve in fluid connection with an outlet of the heater and a first end of a fluid process loop; and
a return valve in fluid connection with a second end of the process fluid loop and a third input of the tank; and
wherein the fluid at the second temperature is configured to exit the heating system at the outlet valve such that the fluid circulates through the fluid process loop and returns back to the tank through the third input of the tank, the tank configured to accept a flow of water from the first input, the second input, and the third input and to combine each flow of water to achieve a desired temperature of the volume of water in the tank.

Item 22. The heating system of Item 21, wherein the flow of water from the first water source is at a third temperature and the flow of water from the second water source is at a fourth temperature, the fourth temperature at a temperature higher than the third temperature.

Item 23. The heating system of Item 21, wherein the first water source is a source of ambient temperature water and the second water source is a source of heated water above ambient temperature.

Item 24. The heating system of Item 21, wherein the second water source is a natural gas-fired water heater.

Item 25. The heating system of Item 21, further comprising first flow controller in line with the first input and a second flow controller in line with the second input, the first flow controller controls an amount of flow of water from the first water source that is sent to the tank and the second flow controller controls an amount of flow of water from the second water source that is sent to the tank.

Item 26. The heating system of Item 25, wherein a controller selectively controls the first flow controller and the second flow controller to achieve a desired temperature setpoint of water within the tank.

Item 27. The heating system of Item 25, wherein the first flow controller and the second flow controller are controlled based on at least one characteristic of heating system.

Item 28. The heating system of Item 27, wherein the at least one characteristic of heating system comprises one or all of:
a temperature of the water within the tank;
a current flow rate of water flowing into the tank from the first water source;
a current flow rate of water flowing into the tank from the second water source;
a current flow rate of water flowing into the tank from the return valve;
a current temperature of water flowing into the tank from the first water source;
a current temperature of water flowing into the tank from the second water source;
a current temperature of water flowing into the tank from the return valve;
a pressure within the fluid process loop;
the first temperature;
a first temperature setpoint;
the second temperature;
a second temperature setpoint; and
a final temperature setpoint, the final temperature setpoint is a desired temperature for water entering the fluid process loop.

Item 29. The heating system of Item 21, further comprising a filter located between the outlet of the heater and the outlet valve.

Item 30. The heating system of Item 21, wherein the fluid is ultra-pure deionized water.

Item 31. The heating system of Item 21, wherein the fluid process loop is a closed loop such that the fluid in the fluid process loop is not exposed to atmosphere.

Item 32. The heating system of Item 21, further comprising a process valve in fluid connection with the fluid process loop, the process valve is configured to route at least a portion of fluid from the fluid process loop to a process tool.

Item 33. The heating system of Item 32, wherein fluid routed to the process tool through the process valve is discarded to a drain after use.

Item 34. The heating system of Item 21, further comprising a drain valve located downstream of the outlet of the heater, wherein the heating system is configured to route at least of a portion of the fluid through the drain valve to promote recycling of fluid in the heating system.

Item 35. The heating system of Item 34, wherein an amount of fluid that is routed through the drain valve is calculated based upon at least one characteristic of the heating system.

Item 36. The heating system of Item 35, wherein the at least one characteristic comprises at least one of:
a temperature of the water within the tank;
a flow rate of water flowing into the tank from the first water source;
a flow rate of water flowing into the tank from the second water source;
a pressure within the process loop; and
a temperature of water within the process loop.

Item 37. A system, comprising:
an ambient temperature water source;
a heated water source;
a process system comprising at least one process tool;
a heater system, comprising:
   a tank with a first input and a second input, the first input configured to accept a flow of water from the ambient temperature water source and the second input configured to accept a flow of water from the heated water source, the tank holding a volume of water at a first temperature;
   a heater in fluid communication with and located downstream of the tank, the heater configured to heat at least a portion of the fluid from the tank from the first temperature to a second temperature higher than the first temperature;
   an outlet valve in fluid connection with an outlet of the heater and a first end of a fluid process loop; and
   a return valve in fluid connection with a second end of the process fluid loop and a third input of the tank; and
   wherein the fluid at the second temperature is configured to exit the heating system at the outlet valve such that the fluid circulates through the fluid process loop and returns back to the tank through the third input of the tank, the tank configured to accept a flow of water from the first input, the second input, and the third input and to combine each flow of water to achieve a desired temperature for the volume of water in the tank.

Item 38. The heating system of Item 37, further comprising first flow controller in line with the first input and a second flow controller in line with the second input, the first flow controller controls an amount of flow of water from the ambient temperature water source that is sent to the tank and the second flow controller controls an amount of flow of water from the heated water source that is sent to the tank.

Item 39. The heating system of Item 38, wherein a controller selectively controls the first flow controller and the second flow controller to achieve a desired temperature setpoint of water within the tank.

Item 40. The heating system of Item 38, wherein the first flow controller and the second flow controller are controlled based on at least one characteristic of heating system.

Item 41. The heating system of Item 40, wherein the at least one characteristic of heating system comprises one or all of:
a temperature of the water within the tank;
a current flow rate of water flowing into the tank from the ambient temperature water source;
a current flow rate of water flowing into the tank from the heated water source;
a current flow rate of water flowing into the tank from the return valve;
a current temperature of water flowing into the tank from the ambient temperature water source;
a current temperature of water flowing into the tank from the heated water source;
a current temperature of water flowing into the tank from the return valve;
a pressure within the fluid process loop;
the first temperature;
a first temperature setpoint;
the second temperature;
a second temperature setpoint; and
a final temperature setpoint, the final temperature setpoint is a desired temperature for water entering the fluid process loop.

Item 42. The heating system of Item 37, further comprising a process valve in fluid connection with the fluid process loop, the process valve is configured to route at least a portion of fluid from the fluid process loop to a process tool, wherein the fluid process loop is a closed loop such that the fluid in the fluid process loop is not exposed to atmosphere.

The word “exemplary” is used herein to mean serving as an example, instance or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Further, at least one of A and B and/or the like generally means A or B or both A and B. In addition, the articles “a” and “an” as used in this application and the appended claims may generally be construed to mean “one or more” unless specified otherwise or clear from context to be directed to a singular form.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims. Of course, those skilled in the art will recognize many modifications may be made to this configuration without departing from the scope or spirit of the claimed subject matter.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure.

In addition, while a particular feature of the disclosure may have been disclosed with respect to only one of several implementations, such feature may be combined with one or more other features of the other implementations as may be desired and advantageous for any given or particular application. Furthermore, to the extent that the terms “includes,” “having,” “has,” “with,” or variants thereof are used in either the detailed description or the claims, such terms are intended to be inclusive in a manner similar to the term “comprising.”

The implementations have been described, hereinabove. It will be apparent to those skilled in the art that the above methods and apparatuses may incorporate changes and modifications without departing from the general scope of this invention. It is intended to include all such modifications and alterations in so far as they come within the scope of the appended claims or the equivalents thereof.

What is claimed is:

1. A heating system, comprising:
a tank with a first input and a second input, the first input configured to accept a flow of water from a first water source and the second input configured to accept a flow of water from a second water source, the tank holding a volume of water at a first temperature;
a heater in fluid communication with and located downstream of the tank, the heater configured to heat at least a portion of the fluid from the tank from the first temperature to a second temperature higher than the first temperature;
an outlet valve in fluid connection with an outlet of the heater and a first end of a fluid process loop; and
a return valve in fluid connection with a second end of the process fluid loop and a third input of the tank; and
wherein the fluid at the second temperature is configured to exit the heating system at the outlet valve such that the fluid circulates through the fluid process loop and returns back to the tank through the third input of the tank, the tank configured to accept a flow of water from the first input, the second input, and the third input and to combine each flow of water to achieve a desired temperature of the volume of water in the tank.

2. The heating system of claim 1, wherein the flow of water from the first water source is at a third temperature and the flow of water from the second water source is at a fourth temperature, the fourth temperature at a temperature higher than the third temperature.

3. The heating system of claim 1, wherein the first water source is a source of ambient temperature water and the second water source is a source of heated water above ambient temperature.

4. The heating system of claim 1, wherein the second water source is a natural gas-fired water heater.

5. The heating system of claim 1, further comprising first flow controller in line with the first input and a second flow controller in line with the second input, the first flow controller controls an amount of flow of water from the first water source that is sent to the tank and the second flow controller controls an amount of flow of water from the second water source that is sent to the tank.

6. The heating system of claim 5, wherein a controller selectively controls the first flow controller and the second flow controller to achieve a desired temperature setpoint of water within the tank.

7. The heating system of claim 5, wherein the first flow controller and the second flow controller are controlled based on at least one characteristic of heating system.

8. The heating system of claim 7, wherein the at least one characteristic of heating system comprises one or all of:
a temperature of the water within the tank;
a current flow rate of water flowing into the tank from the first water source;
a current flow rate of water flowing into the tank from the second water source;
a current flow rate of water flowing into the tank from the return valve;
a current temperature of water flowing into the tank from the first water source;
a current temperature of water flowing into the tank from the second water source;
a current temperature of water flowing into the tank from the return valve;
a pressure within the fluid process loop;
the first temperature;
a first temperature setpoint;
the second temperature;
a second temperature setpoint; and
a final temperature setpoint, the final temperature setpoint is a desired temperature for water entering the fluid process loop.

9. The heating system of claim 1, further comprising a filter located between the outlet of the heater and the outlet valve.

10. The heating system of claim 1, wherein the fluid is ultra-pure deionized water.

11. The heating system of claim 1, wherein the fluid process loop is a closed loop such that the fluid in the fluid process loop is not exposed to atmosphere.

12. The heating system of claim 1, further comprising a process valve in fluid connection with the fluid process loop, the process valve is configured to route at least a portion of fluid from the fluid process loop to a process tool.

13. The heating system of claim 12, wherein fluid routed to the process tool through the process valve is discarded to a drain after use.

14. The heating system of claim 1, further comprising a drain valve located downstream of the outlet of the heater, wherein the heating system is configured to route at least of a portion of the fluid through the drain valve to promote recycling of fluid in the heating system.

15. The heating system of claim 14, wherein an amount of fluid that is routed through the drain valve is calculated based upon at least one characteristic of the heating system.

16. The heating system of claim 15, wherein the at least one characteristic comprises at least one of:
a temperature of the water within the tank;
a flow rate of water flowing into the tank from the first water source;
a flow rate of water flowing into the tank from the second water source;
a pressure within the fluid process loop; and
a temperature of water within the process loop.

17. A system, comprising:
an ambient temperature water source;
a heated water source;
a process system comprising at least one process tool;
a heater system, comprising:
a tank with a first input and a second input, the first input configured to accept a flow of water from the ambient temperature water source and the second input configured to accept a flow of water from the heated water source, the tank holding a volume of water at a first temperature;
a heater in fluid communication with and located downstream of the tank, the heater configured to heat at least a portion of the fluid from the tank from the first temperature to a second temperature higher than the first temperature;
an outlet valve in fluid connection with an outlet of the heater and a first end of a fluid process loop; and
a return valve in fluid connection with a second end of the process fluid loop and a third input of the tank; and
wherein the fluid at the second temperature is configured to exit the heating system at the outlet valve such that the fluid circulates through the fluid process loop and returns back to the tank through the third input of the tank, the tank configured to accept a flow of water from the first input, the second input, and the third input and to combine each flow of water to achieve a desired temperature for the volume of water in the tank.

18. The heating system of claim 17, further comprising first flow controller in line with the first input and a second flow controller in line with the second input, the first flow controller controls an amount of flow of water from the ambient temperature water source that is sent to the tank and the second flow controller controls an amount of flow of water from the heated water source that is sent to the tank.

19. The heating system of claim 18, wherein a controller selectively controls the first flow controller and the second flow controller to achieve a desired temperature setpoint of water within the tank.

20. The heating system of claim 18, wherein the first flow controller and the second flow controller are controlled based on at least one characteristic of heating system, the at least one characteristic of heating system comprises one or all of:
a temperature of the water within the tank;
a current flow rate of water flowing into the tank from the ambient temperature water source;
a current flow rate of water flowing into the tank from the heated water source;
a current flow rate of water flowing into the tank from the return valve;
a current temperature of water flowing into the tank from the ambient temperature water source;
a current temperature of water flowing into the tank from the heated water source;
a current temperature of water flowing into the tank from the return valve;
a pressure within the fluid process loop;
the first temperature;
a first temperature setpoint;
the second temperature;
a second temperature setpoint; and
a final temperature setpoint, the final temperature setpoint is a desired temperature for water entering the fluid process loop.
